(19) United States
(12) Patent Application Publication
(10) Pub. No.: US 2025/0220893 A1
(43) Pub. Date: Jul. 3, 2025

(54) SEMICONDUCTOR MEMORY DEVICE

(71) Applicant: Samsung Electronics Co., Ltd., Suwon-si (KR)

(72) Inventors: Sang Hyun SUNG, Suwon-si (KR); Seok Han PARK, Suwon-si (KR); Gyu Hwan OH, Suwon-si (KR); Bo Won YOO, Suwon-si (KR); Jin Woo HAN, Suwon-si (KR)

(73) Assignee: Samsung Electronics Co., Ltd., Suwon-si (KR)

(21) Appl. No.: 18/891,310

(22) Filed: Sep. 20, 2024

(30) Foreign Application Priority Data
Dec. 28, 2023 (KR) 10-2023-0194997

(51) Int. Cl. H10B 12/00

(52) U.S. Cl. CPC H10B 12/50; H10B 12/09; H10B 12/315; H10B 12/482

(57) ABSTRACT

A semiconductor device including a peri-gate structure, a shielding conductive pattern on the peri-gate structure including shielding line patterns extending in a first direction, bit lines between the shielding line patterns on the peri-gate structure, first and second active patterns on the bit line, a back gate electrode on the bit line and the shielding conductive pattern between the first and second active patterns, first and second word lines adjacent to the first and second active patterns, and a data storage pattern on the first and second active pattern, and connected to the first and second active pattern, the bit line includes a first and second portion of the bit line, the first portion of the bit line overlaps the shielding line pattern in the second direction, and the second portion of the bit line does not overlap the shielding line pattern in the second direction.

### CROSS-REFERENCE TO RELATED APPLICATION

This application claims priority from Korean Patent Application 10-2023-0194997 filed on Dec. 28, 2023 in the Korean Intellectual Property Office and all the benefits accruing therefrom under 35 U.S.C. § 119, the contents of which in its entirety are herein incorporated by reference.

### BACKGROUND

The present disclosure relates to semiconductor memory devices, and more particularly, to semiconductor memory devices including a vertical channel transistor (VCT).

There is a need to increase a degree of integration of the semiconductor memory device to satisfy superior performance and lower prices required by consumers. In the case of the semiconductor memory device, an increased degree of integration is especially required because the degree of integration is an important factor in determining the price of the product.

In the case of a two-dimensional or planar semiconductor memory device, the degree of integration thereof is mainly determined by an area occupied by a unit memory cell, and is therefore greatly influenced by a level of fine pattern formation technique. However, since ultra-expensive apparatuses are required to miniaturize the pattern, the degree of integration of the two-dimensional semiconductor memory device is increasing, but is still limited. Accordingly, semiconductor memory devices that include vertical channel transistors whose channels extend in a vertical direction have been proposed.

### SUMMARY

Aspects of the present disclosure provide a semiconductor memory device having improved degree of integration and electrical characteristics.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some aspects of the present disclosure, there is provided a semiconductor memory device including a peri-gate structure on a substrate; a shielding conductive pattern on the peri-gate structure, the shielding conductive pattern including shielding line patterns extending in a first direction; a bit line between the shielding line patterns adjacent in a second direction on the peri-gate structure, the bit lines extend in the first direction; first and second active patterns which alternate on the bit line in the first direction; a back gate electrode on the bit line and the shielding conductive pattern, the back gate electrode between the first and second active patterns adjacent to each other, the back gate electrode extending in the second direction; a first word line adjacent to the first active patterns, and extend in the second direction; second word lines adjacent to the second active patterns, the second word lines extending in the second direction; and a data storage pattern on the first active pattern and the second active pattern, the data storage pattern connected to the first active pattern and the second active pattern, wherein the bit line includes a first portion of the bit line and a second portion on at least one side of the first portion of the bit line, the first portion of the bit line overlaps the shielding line patterns in the second direction, and the second portion of the bit line does not overlap the shielding line patterns in the second direction.

According to another aspect of the present disclosure, there is provided a semiconductor memory device including a peri-gate structure on a substrate; a shielding conductive pattern on the peri-gate structure, the shielding conductive pattern including a first shielding plate and a plurality of shielding line patterns, each shielding line pattern of the plurality of shielding line patterns extending in a first direction; a bit line on the peri-gate structure between shielding line patterns of the plurality of shielding line patterns adjacent in a second direction, the bit line extend in the first direction; first and second active patterns which alternate on the bit line in the first direction; a back gate electrode on the bit line and the shielding conductive pattern, the back gate electrode between the first and second active patterns adjacent to each other, the back gate electrode extending in the second direction; first word lines adjacent to the first active patterns, the first word lines extending in the second direction; second word lines adjacent to the second active patterns, the second word lines extending in the second direction; and a data storage pattern on the first active pattern and the second active pattern, the data storage pattern connected to the first active pattern and the second active pattern, wherein each of the plurality of shielding line patterns includes a first portion that overlaps the first shielding plate in a vertical direction and a second portion that does not overlap the first shielding plate in the vertical direction.

According to still another aspect of the present disclosure, there is provided a semiconductor memory device including a peri-gate structure on a substrate; a bit line on the peri-gate structure, the bit line extending in a first direction; a shielding conductive pattern on the peri-gate structure between bit lines adjacent in a second direction, the shielding conductive pattern including a plurality of shielding line patterns extending in the first direction; first and second active patterns which alternate on the bit line in the first direction; a back gate electrode on the bit line and the shielding conductive pattern, the back gate electrode extending in the second direction between adjacent first and second active patterns; first word lines adjacent to the first active patterns and extending in the second direction; second word lines adjacent to the second active patterns and extending in the second direction; and a data storage pattern on the first active pattern and the second active pattern, the data storage pattern is connected to the first active pattern and the second active pattern, wherein a part of the bit line protrudes beyond the plurality of shielding line patterns in the first direction, the bit line includes a bottom surface facing the peri-gate structure, and an upper surface facing the first and second active patterns, and the shielding conductive pattern is not on the bottom surface of the bit line.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout diagram of a semiconductor memory device according to some example embodiments.

FIG. 2 is a layout diagram of a boundary portion between a cell array region and a peripheral circuit region of FIG. 1.

FIG. 3 is a cross-sectional view taken along lines A-A and B-B of FIG. 2.

FIG. 4 is a cross-sectional view taken along lines C-C and D-D of FIG. 2.

FIG. 5 is an enlarged view of a portion P of FIG. 3.

FIG. 6 is an enlarged view of a portion Q of FIG. 3.

FIG. 7 is an example diagram for explaining a placement shape of bit lines and shielding conductive patterns in the cell array region as in FIG. 2.

FIG. 8 is an example perspective view for explaining the shape of the shielding conductive pattern.

FIGS. 9 and 10 are diagrams for explaining a semiconductor memory device according to some example embodiments.

FIG. 11 is a diagram for explaining the semiconductor memory device according to some example embodiments.

FIGS. 12 and 13 are diagrams for explaining the semiconductor memory device according to some example embodiments.

FIGS. 14 to 18 are diagrams for explaining a semiconductor memory device according to some example embodiments.

FIGS. 19 and 20 are diagrams for explaining a semiconductor memory device according to some example embodiments, respectively.

FIGS. 21 to 24 are diagrams for explaining a semiconductor memory device according to some example embodiments, respectively.

FIGS. 25 to 56 are intermediate stage diagrams for explaining a method for fabricating a semiconductor memory device according to example some embodiments.

### DETAILED DESCRIPTION

It should be understood that, although the terms first, second, third, etc., may be used herein to describe various elements, regions, layers and/or sections, these elements, regions, layers, and/or sections should not be limited by these terms. These terms are only used to distinguish one element, region, layer, or section from another region, layer, or section. Thus, a first element, component, region, layer, or section discussed below could be termed a second element, region, layer, or section without departing from the teachings of example embodiments.

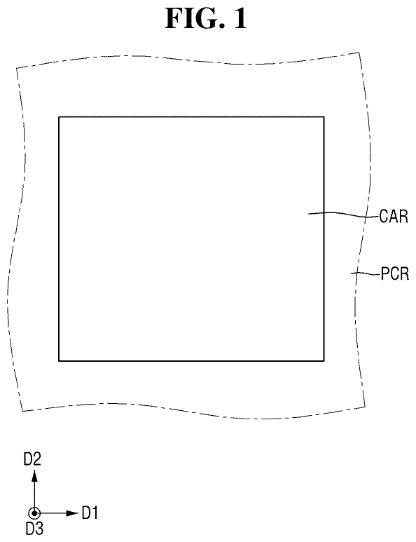

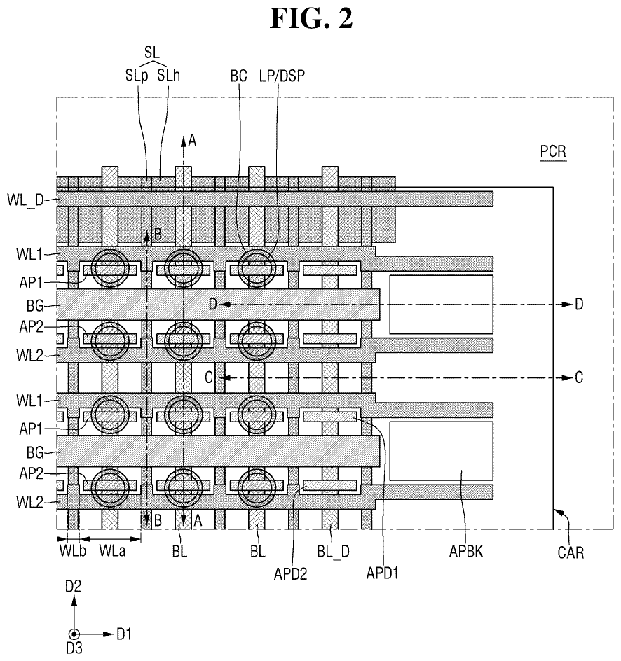

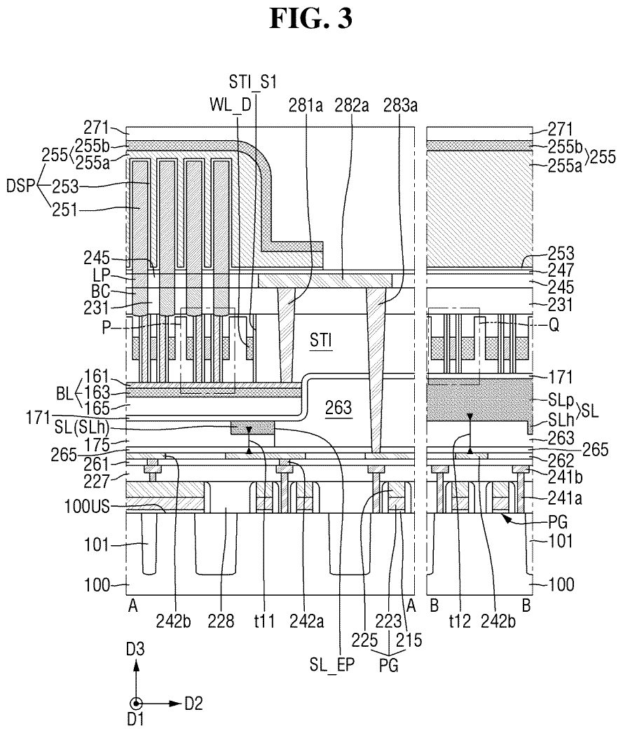

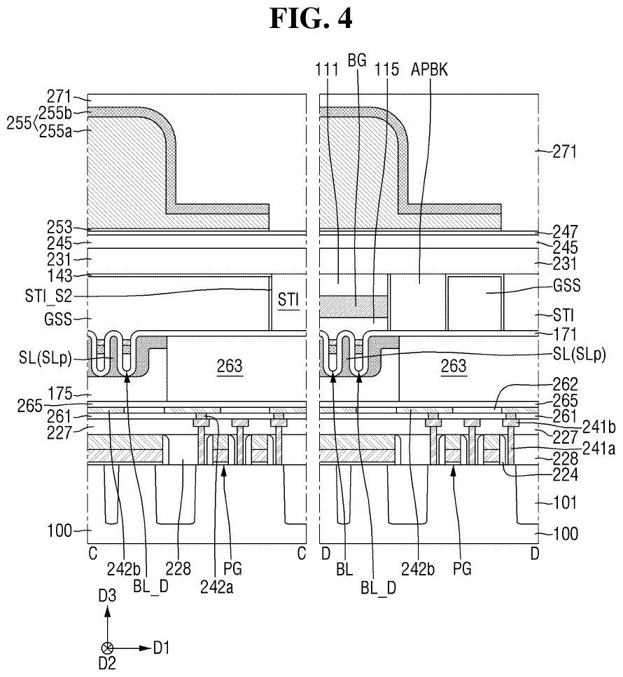

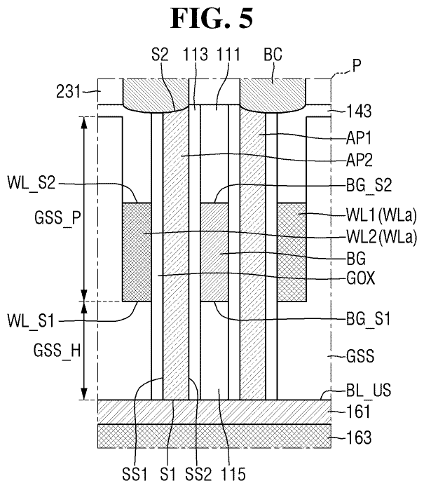

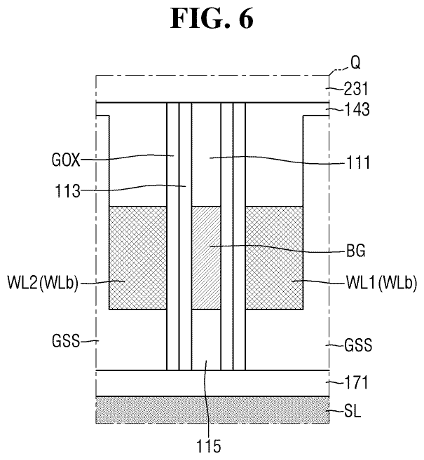

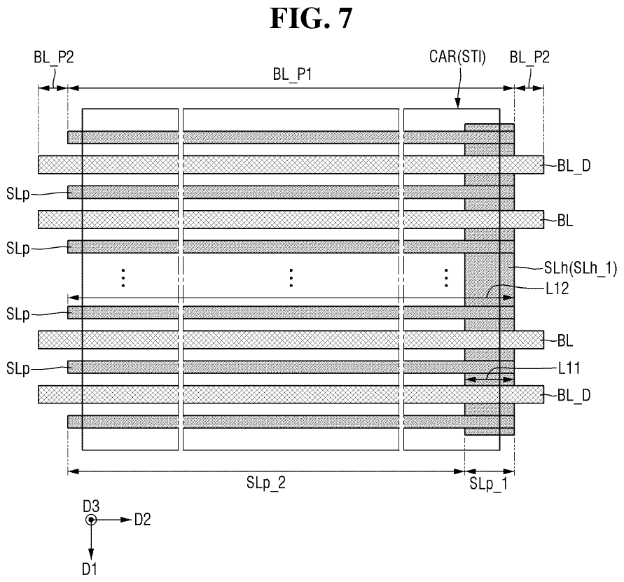

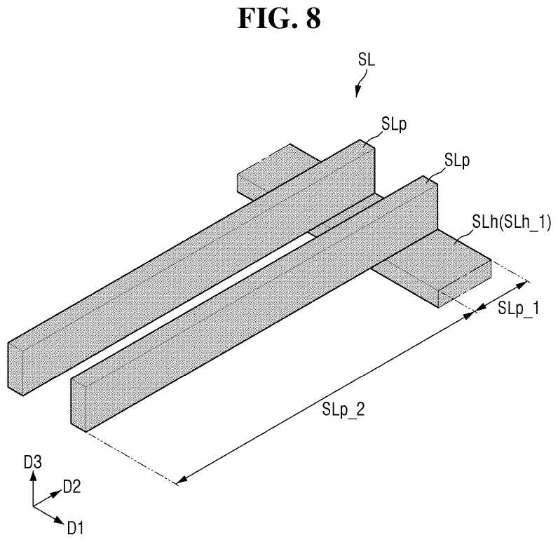

FIG. 1 is a layout diagram of a semiconductor memory device according to some example embodiments. FIG. 2 is a layout diagram of a boundary portion between a cell array region and a peripheral circuit region of FIG. 1. FIG. 3 is a cross-sectional view taken along lines A-A and B-B of FIG. 2. FIG. 4 is a cross-sectional view taken along lines C-C and D-D of FIG. 2. FIG. 5 is an enlarged view of a portion P of FIG. 3. FIG. 6 is an enlarged view of a portion Q of FIG. 3. FIG. 7 is an example diagram for explaining a placement shape of bit lines and shielding conductive patterns in the cell array region as in FIG. 2. FIG. 8 is an example perspective view for explaining the shape of the shielding conductive pattern.

The semiconductor memory device according to some example embodiments of the present disclosure may include memory cells including a vertical channel transistor (VCT).

Referring to FIGS. 1 to 8, the semiconductor memory device according to some example embodiments may include bit lines BL, word lines WL1 and WL2, back gate electrodes BG, a shielding conductive pattern SL, active patterns AP1 and AP2, and data storage patterns DSP.

The substrate 100 may be a silicon substrate, or may include other materials, for example, but not limited to, silicon germanium, indium antimonide, lead telluride, indium arsenide, indium phosphide, gallium arsenide or gallium antimonide.

The substrate 100 may include an upper surface 100US. An element isolation film 101 may be disposed inside the substrate 100. The element isolation film 101 may define an active region inside the substrate 100. The element isolation film 101 includes an insulating material.

The substrate 100 may include a cell array region CAR in which a data storage pattern DSP is disposed, and a peripheral circuit region PCR defined around the cell array region CAR. A cell region element isolation film STI may be disposed on the peripheral circuit region PCR of the substrate 100. From viewpoint of a plan view, the cell region element isolation film STI may define the cell array region CAR of the substrate 100.

A peri-gate structure PG may be disposed on the substrate 100. For example, the peri-gate structure PG may be disposed on the upper surface 100US of the substrate. The peri-gate structure PG may be disposed over the cell array region CAR and the peripheral circuit region PCR. In other words, a part of the peri-gate structure PG may be disposed in the cell array region of the substrate 100, and the remainder of the peri-gate structure PG may be disposed in the peripheral circuit region of the substrate 100.

The peri-gate structure PG may be included in a sensing transistor, a transfer transistor, a drive transistor, and/or the like. For example, the peri-gate structure PG included in the sensing transistor may be disposed on the substrate 100 of the cell array region CAR, but is not limited thereto. It goes without saying that the types of transistors disposed on the substrate 100 of the cell array region CAR may vary depending on the design and placement of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a higher dielectric constant than a silicon oxide film, or a combination thereof. The high dielectric constant insulating film may include, for example, but not limited to, at least one of metal oxide, metal oxynitride, metal silicon oxide, and metal silicon oxynitride.

The peri-lower conductive pattern 223 and the peri-upper conductive pattern 225 each include a conductive material. For example, the peri-lower conductive pattern 223 and the peri-upper conductive pattern 225 may each include at least one of a doped semiconductor material, conductive metal nitride, conductive metal silicon nitride, metal carbonitride, conductive metal silicide, conductive metal oxide, a two-dimensional (2D) material, and/or a metal. In the semiconductor device according to some example embodiments, the two-dimensional material may be a metallic material and/or a semiconductor material. The 2D material may include a 2D allotrope or a 2D compound, and may include, but not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed as an example, the 2D materials that may be included in the semiconductor memory device of the present disclosure are not limited by the above-mentioned materials. Although the peri-gate structure PG is shown to include a plurality of conductive patterns, the example embodiments are not limited thereto.

The peri-gate spacer 224 may be disposed on the side wall of the peri-gate structure PG. The peri-gate spacer 224 includes an insulating material.

Although not shown, the peri-gate structure PG may further include a peri-gate mask pattern disposed on the peri-upper conductive pattern 225. The peri-gate mask pattern is made up of an insulating material.

The first peri-lower insulating film 227 and the second peri-lower insulating film 228 are disposed on the upper surface 100US of the substrate. The first peri-lower insulating film 227 and the second peri-lower insulating film 228 each include an insulating material.

A peri-contact plug 241a and a peri-wiring line 241b may be disposed in the first peri-lower insulating film 227 and the second peri-lower insulating film 228. The peri-contact plug 241a and the peri-wiring line 241b may be connected to the conductive patterns 223 and 225 of the peri-gate structure PG. Although not shown, the peri-contact plug 241a and the peri-wiring line 241b may be connected to a source/drain region disposed on at least one side of the peri-gate structure PG.

Although the peri-contact plug 241a and the peri-wiring line 241b are shown as being different films, the present disclosure is not limited thereto. A boundary between the peri-contact plug 241a and the peri-wiring line 241b may not be distinguished. The peri-contact plug 241a and the peri-wiring line 241b each include a conductive material.

The first peri-upper insulating film 261 and the second peri-upper insulating film 262 may be disposed on the peri-contact plug 241a and the peri-wiring line 241b. The first peri-upper insulating film 261 and the second peri-upper insulating film 262 each include an insulating material. It goes without saying that, unlike the shown example, an insulating film formed of a single film may be disposed on the peri-contact plug 241a and the peri-wiring line 241b.

Peri-connecting structures 242a and 242b may be connected to the peri-wiring line 241b. The peri-connecting structures 242a and 242b may include a peri-connecting via 242a and a peri-connecting wiring 242b. The peri-connecting via 242a and the peri-connecting wiring 242b each include a conductive material.

Although the peri-connecting via 242a and the peri-connecting wiring 242b are shown as being different films from each other, the example embodiments are not limited thereto. Although the peri-connecting structures 242a and 242b are shown to include one peri-connecting trace 242b disposed on one metal level, this is only for convenience of explanation and the example embodiments are not limited thereto. The peri-connecting structures 242a and 242b may include a plurality of peri-connecting traces 242b disposed on different metal levels from each other.

The third peri-upper insulating film 265 may be disposed on the peri-connecting structures 242a and 242b. The third peri-upper insulating film 265 includes an insulating material.

Bit lines BL may be disposed on the peri-gate structure PG on the substrate 100. For example, the bit lines BL may be disposed on the peri-connecting structures 242a and 242b.

The bit line BL may extend long in a second direction D2. Adjacent bit lines BL may be spaced apart in a first direction D1. The bit line BL may include a long side wall extending in the second direction D2, and a short side wall extending in the first direction D1.

Each bit line BL may extend from the cell array region CAR to the peripheral circuit region PCR. An end portion of each bit line BL may be disposed on the peripheral circuit region PCR. A part of the bit line BL may overlap the cell region element isolation film STI surrounding the cell array region CAR in a third direction D3. For example, the bit line BL may be overlapped by the cell region element isolation film STI in a third direction D3.

A dummy bit line BL_D may be disposed on the peri-gate structure PG on the substrate 100. The dummy bit line BL_D may be disposed on the peri-connecting structures 242a and 242b.

The dummy bit line BL_D may extend in the second direction D2. For example, the dummy bit line BL_D may be disposed at an outer corner of the cell array region CAR. The bit lines BL may be disposed between the dummy bit lines BL_D disposed along the outer corner of the cell array region CAR.

The dummy bit line BL_D may extend from the cell array region CAR to the peripheral circuit region PCR. The end portion of the dummy bit line BL_D may be disposed on the peripheral circuit region PCR. For example, the dummy bit line BL_D may be disposed in a portion of the cell array region CAR that overlaps the back gate electrodes BG in the third direction D3. In other words, a part of the dummy bit line BL_D may overlap the back gate electrodes BG in the third direction D3. From viewpoint of a plan view, the dummy bit line BL_D may intersect the back gate electrode BG. Unlike the shown example, the dummy bit line BL_D may not include a portion that overlaps the back gate electrode BG in the third direction D3.

Unlike the shown example, as an example, a plurality of dummy bit lines BL_D may be disposed along the boundary between the cell array region CAR and the peripheral circuit region PCR. As another example, the dummy bit line BL_D may not be disposed on the cell array region CAR.

The bit line BL and the dummy bit line BL_D may include a semiconductor pattern 161, a metal pattern 163, and a line mask pattern 165 that are stacked in this order. The dummy bit line BL_D has the same structure as that of the bit line BL.

Although a width of the dummy bit line BL_D in the first direction D1 is shown as being the same as a width of the bit line BL in the first direction D1, the example embodiments are not limited thereto. The width of the dummy bit line BL_D in the first direction D1 may be larger than the width of the bit line BL in the first direction D1.

The bit line BL and the dummy bit line BL_D may include conductive bit lines. The conductive bit line may be a film including a conductive material among the bit line BL and the dummy bit line BL_D. The conductive bit line may include, for example, a semiconductor pattern 161 and a metal pattern 163.

The semiconductor pattern 161 may include a conductive semiconductor material. The conductive semiconductor material may be, for example, a semiconductor material doped with impurities. The semiconductor pattern 161 may include at least one of poly silicon, poly silicon germanium, poly germanium, amorphous silicon, amorphous silicon germanium, and/or amorphous germanium. The metal pattern 163 may include a conductive material including metal. The metal pattern 163 may include, for example, at least one of conductive metal nitride, conductive metal silicon nitride, metal carbonitride, conductive metal silicide, conductive metal oxide, a two-dimensional material, and a metal. A line mask pattern 165 may include an insulating material. The line mask pattern 165 may include, but not limited to, silicon nitride, silicon oxynitride or the like.

Unlike the shown example embodiments, as an example, the bit line BL and the dummy bit line BL_D may each include one of the semiconductor pattern 161 and the metal pattern 163. As another example embodiment, the bit line BL and the dummy bit line BL_D may not include the line mask pattern 165.

Shielding structures 171, SL and 175 may be disposed on the peri-gate structure PG on the substrate 100. For example, the shielding structures 171, SL, and 175 may be disposed on the peri-connecting structures 242a and 242b.

The shielding structures 171, SL, and 175 may include a shielding conductive pattern SL and shielding insulation films 171 and 175. For example, the shielding insulation films 171 and 175 may include a shielding insulation liner 171 and a shielding insulation capping film 175.

In the semiconductor memory device according to some example embodiments, the shielding conductive pattern SL may include a shielding conductive plate SLh and a plurality of shielding conductive line patterns SLp. For example, the shielding conductive pattern SL may include a first shielding conductive plate SLh_1 and a plurality of shielding conductive line patterns SLp.

The first shielding conductive plate SLh_1 may have a flat plate shape. The first shielding conductive plate SLh_1 may be disposed on the cell array region CAR. A part of the first shielding conductive plate SLh_1 may be, but not limited to, disposed over the peripheral circuit region PCR.

Each shielding conductive protruding pattern SLp may protrude from the first shielding conductive plate SLh in the third direction D3. For example, the third direction D3 may be a vertical direction that is perpendicular to the substrate 100. Each shielding conductive line pattern SLp is connected, for example directly connected, to the first shielding conductive plate SLh_1.

Each shielding conductive line pattern SLp may protrude toward word lines WL1 and WL2. Each shielding conductive line pattern SLp may extend in the second direction D2. Each shielding conductive line pattern SLp may be adjacent to each other in the first direction D1. For example, the first direction D1 and the second direction D2 may be horizontal directions that are horizontal to the substrate 100.

A part of the shielding conductive line pattern SLp may overlap the first shielding conductive plate SLh_1 in the third direction D3. A length L12 of the shielding conductive line pattern SLp in the second direction D2 is greater than a length L11 of the first shielding conductive plate SLh_1 in the second direction D2.

In other words, each shielding conductive line pattern SLp may include a first portion SLp_1 and a second portion SLp_2. The first portion SLp_1 of the shielding conductive line pattern may overlap the first shielding conductive plate SLh_1 in the third direction D3. The second portion SLp_2 of the shielding conductive line pattern does not overlap the first shielding conductive plate SLh_1 in the third direction D3.

The shielding conductive pattern SL may include a terminal end SL_EP. The terminal end SL_EP of the shielding conductive pattern may be located at an edge of the shielding conductive pattern SL in the second direction D2. When the shielding conductive plate SLh is disposed on one side of the shielding conductive line pattern SLp and not on the other side of the shielding conductive line pattern SLp, one terminal end SL_EP of the shielding conductive pattern SL may be included in the shielding conductive line pattern SLp and the first shielding conductive plate SLh_1, and the other terminal end SL_EP of the shielding conductive pattern SL may be included in the shielding conductive line pattern SLp.

In the semiconductor memory device according to some example embodiments, the bit lines BL may be disposed on the shielding conductive pattern SL. Each bit line BL may be disposed on the first shielding conductive plate SLh_1. The bit line BL may be disposed between the shielding conductive line patterns SLp adjacent to each other in the first direction D1.

A part of the bit line BL may overlap the shielding conductive line pattern SLp in the first direction D1. An extension length of the bit line BL in the second direction D2 may be greater than an extension length L12 of the shielding conductive line pattern SLp in the second direction D2.

In other words, each bit line BL may include a first portion BL_P1 and a second portion BL_P2. The second portion BL_P2 of the bit line may be disposed on at least one side of the first portion BL_P1 of the bit line. In the semiconductor memory device according to some example embodiments, the second portion BL_P2 of the bit line may be disposed on either side of the first portion BL_P1 of the bit line. For example, in some example embodiments, the second portion BL_P2 may be on both sides of the first portion BL_P1 of the bit line.

The first portion BL_P1 of the bit line may overlap the shielding conductive line pattern SLp in the first direction D1. The second portion BL_P2 of the bit line may not overlap the shielding conductive line pattern SLp in the first direction D1.

A part of the bit line BL may protrude in the second direction D2 beyond the shielding conductive line pattern SLp. The second portion BL_P2 of the bit line may protrude in the second direction D2 beyond the shielding conductive line pattern SLp.

When the shielding conductive pattern SL includes the first shielding conductive plate SLh_1, unlike the shown example, the length of the bit line BL in the second direction D2 may be equal to the length L12 of the shielding conductive line pattern SLp in the second direction D2.

The shielding insulation capping film 175 may be disposed on the peri-connecting structures 242a and 242b. The shielding insulation capping film 175 may be disposed between the peri-gate structure PG and the shielding conductive pattern SL. The shielding insulation capping film 175 may be in contact with the shielding conductive pattern SL.

The shielding insulation capping film 175 may include a first portion and a second portion. The first portion of the shielding insulation capping film 175 may overlap the first portion SLp_1 of the shielding conductive line pattern in the third direction D3. The first portion of the shielding insulation capping film 175 may overlap the first shielding conductive plate SLh_1 in the third direction D3. For example, the first shielding conductive plate SLh_1 may overlap the shielding insulation capping film 175 in the third direction D3. The second portion of the shielding insulation capping film 175 may overlap the second portion SLp_2 of the shielding conductive line pattern in the third direction D3. The second portion of the shielding insulation capping film 175 may not overlap the first shielding conductive plate SLh_1 in the third direction D3.

A thickness t11 of the first portion of the shielding insulation capping film 175 between the first portion SLp_1 of the shielding conductive line pattern and the peri-gate structure PG is smaller than a thickness t12 of the second portion of the shielding insulation capping film 175 between the second portion SLp_2 of the shielding conductive line pattern and the peri-gate structure PG.

Although the shielding insulation capping film 175 is shown to be a single film, this is only for convenience of explanation, and the example embodiment is not limited thereto. Unlike the shown example, the shielding insulation capping film 175 may include a plurality of insulating films.

Unlike the shown example, the first portion of the shielding insulation capping film 175 may include a different material from the second portion of the shielding insulation capping film 175. An interface may exist between the first portion of the shielding insulation capping film 175 and the second portion of the shielding insulation capping film 175.

An outer boundary of the shielding insulation capping film 175 may be defined by the shielding conductive pattern SL. In other words, the shielding insulation capping film 175 may be disposed in a portion that overlaps the shielding conductive pattern SL in the third direction D3. Further, the shielding insulation capping film 175 may be disposed in a portion that overlaps the bit line BL in the third direction between the shielding conductive line patterns SLp in a horizontal direction such as the D2 direction.

The shielding insulation liner 171 may be disposed on the shielding conductive pattern SL. The shielding insulation liner 171 may extend along the profile of the shielding conductive line pattern SLp. For example, the shielding insulation liner may extend in a horizontal direction such as the first direction D1 or the second direction D2. The shielding insulation liner 171 does not extend along the side wall of the shielding conductive pattern SL. The side wall of the shielding conductive pattern SL may define a boundary of the shielding conductive pattern SL. The shielding conductive pattern SL may be disposed between the shielding conductive liner 171 and the shielding insulation capping film 175.

A part of the shield insulation liner 171 may extend along the upper surface of the first upper insulating film 263. The first upper insulating film 263 may be disposed on the third peri-upper insulating film 265. The first upper insulating film 263 may cover a side wall of the shielding conductive pattern SL.

The shielding conductive pattern SL includes a conductive material. The shielding conductive pattern SL may include, for example, at least one of a conductive metal nitride, a conductive metal silicon nitride, a metal carbonitride, a conductive metal silicide, a conductive metal oxide, a two-dimensional material, and/or a metal. The shielding insulation liner 171, the shielding insulation capping film 175, and the first upper insulating film 263 each include an insulating material. Depending on the materials included in the shielding insulation liner 171 and the first upper insulating film 263, the boundary between the shielding insulation liner 171 and the first upper insulating film 263 may not be distinguished. Further, depending on the materials included in the shielding insulation capping film 175 and the first upper insulating film 263, the boundary between the shielding insulation capping film 175 and the first upper insulating film 263 may not be distinguished.

Since the shielding conductive pattern SL is disposed between the bit lines BL adjacent to each other in the first direction D1, a coupling noise between the bit lines BL may be reduced. On the other hand, when the shielding conductive plate is disposed entirely in the cell array region CAR, noise due to the shielding conductive plate may occur. Furthermore, a capacitance between the shielding conductive plate and the bit line BL may be increased.

Since the first shielding conductive plate SLh_1 is disposed to overlap a part of the shielding conductive line pattern SLp, noise may be reduced by the first shielding conductive plate SLh_1. Furthermore, the capacitance between the first shielding conductive plate SLh_1 and the bit line BL may be reduced. Accordingly, the performance and reliability of the semiconductor memory device may be improved.

The cell region element isolation film STI may be disposed on the substrate 100. The cell region element isolation film STI may be spatially separated from the upper surface 100US of the substrate. The cell region element isolation film STI may be disposed on the first upper insulating film 263. The shielding insulation liner 171 may be disposed between the cell region element isolation film STI and the first upper insulating film 263.

The cell region element isolation film STI may include a first cell region side wall STI_S1 and a second cell region side wall STI_S2. The first cell region side wall STI_S1 may extend in the first direction D1. The second cell region side wall STI_S2 may extend in the second direction D2.

From viewpoint of a plan view, the cell region element isolation film STI may define a cell array region CAR in which the word lines WL1 and WL2, the back gate electrodes BG, the active patterns AP1 and AP2, the active pattern isolation structures APBK and the like are disposed. In other words, the word lines WL1 and WL2, the back gate electrodes BG, the active patterns AP1 and AP2, and the active pattern isolation structures APBK may be disposed inside the cell array region CAR. Although the cell region element isolation film STI is shown as being a single film, the example embodiments are not limited thereto. The cell region element isolation film STI includes an insulating material.

The first active patterns AP1 and the second active patterns AP2 may be disposed on each bit line BL. The first active patterns AP1 and the second active patterns AP2 may be alternately disposed along the second direction D2.

The first active patterns AP1 may be spaced apart from each other in the first direction D1. The first active patterns AP1 may be spaced apart at regular intervals. The second active patterns AP2 may be spaced apart from each other in the first direction D1. The second active patterns AP2 may be spaced apart at regular intervals. The first active pattern AP1 may be spaced apart from the second active pattern AP2 in the second direction D2. The first active patterns AP1 and the second active patterns AP2 may be arranged two-dimensionally along the first direction D1 and the second direction D2 that intersect each other.

For example, the first active pattern AP1 and the second active pattern AP2 may each be made of a single crystal semiconductor material. As an example, the first active pattern AP1 and the second active pattern AP2 may each be made of single crystal silicon.

Each of the first active pattern AP1 and the second active pattern AP2 may have a length in the first direction D1, a width in the second direction D2, and a height in the third direction D3. Each of the first active pattern AP1 and the second active pattern AP2 may have a substantially uniform width. That is, each of the first active pattern AP1 and the second active pattern AP2 may have substantially the same width on the first and second surfaces S1 and S2.

Further, the width of the first active pattern AP1 may be equal to the width of the second active pattern AP2.

The width of the first active pattern AP1 and the width of the second active pattern AP2 may range from several nm to several tens of nm. For example, the width of the first active pattern AP1 and the width of the second active pattern AP2 may be, but not limited to, 1 nm to 30 nm, more preferably 1 nm to 10 nm. The length of each of the first and second active patterns AP1 and AP2 may be greater than the line width of the bit line BL. That is, the length of each of the first and second active patterns AP1 and AP2 may be greater than the width of the bit line BL in the first direction D1.

Each of the first active pattern AP1 and the second active pattern AP2 includes a first surface S1 and a second surface S2 that are opposite to each other in the third direction D3. For example, the first surface S1 of the first and second active patterns AP1 and AP2 looks at the bit line BL. The second surfaces S2 of the first and second active patterns AP1 and AP2 looks at (e.g. faces) the contact pattern BC.

The first surfaces S1 of the first and second active patterns AP1 and AP2 are connected to the bit line BL. For example, the first surfaces S1 of the first and second active patterns AP1 and AP2 may be connected to the semiconductor pattern 161 of the bit line BL. Unlike the shown example, when the semiconductor pattern 161 is omitted, the first surfaces S1 of the first and second active patterns AP1 and AP2 may be connected to the metal pattern 163. The second surfaces S2 of the first and second active patterns AP1 and AP2 may be connected to the contact pattern BC.

Each of the first active pattern AP1 and the second active pattern AP2 may include a first side wall SS1 and a second side wall SS2 that are opposite to each other in the second direction D2. The second side wall SS2 of the first active pattern AP1 may face the first side wall SS1 of the second active pattern AP2.

The second side wall SS2 of the first active pattern AP1 may be adjacent to the first word line WL1. The first side wall SS1 of the second active pattern AP2 may be adjacent to the second word line WL2.

Although not shown, as an example, each of the first and second active patterns AP1 and AP2 may include a first dopant region adjacent to the bit line BL, and a second dopant region adjacent to the contact pattern BC. Each of the first active pattern AP1 and the second active pattern AP2 may include a channel region between the first dopant region and the second dopant region. The first dopant region and the second dopant region are regions in which a dopant is doped in the first active pattern AP1 and the second active pattern AP2. Unlike the aforementioned example, each of the first active pattern AP1 and the second active pattern AP2 may not include at least one of the first dopant region and the second dopant region.

At the time of operation of the semiconductor memory device, the channel regions of the first and second active patterns AP1 and AP2 may be controlled by the first and second word lines WL1 and WL2 and the back gate electrodes BG. Since the first and second active patterns AP1 and AP2 are made of a single crystal semiconductor material, leakage current characteristics of the semiconductor memory device may be improved.

The first dummy active patterns APD1 and the second dummy active patterns APD2 may be disposed on the dummy bit line BL_D. The first dummy active patterns APD1 and the second dummy active patterns APD2 may be alternately arranged along the second direction D2.

The first dummy active pattern APD1 may be spaced apart from the first active pattern AP1 in the first direction D1. The first active pattern AP1 and the first dummy active pattern APD1 may be arranged in the first direction D1. The second dummy active pattern APD2 may be spaced apart from the second active pattern AP2 in the first direction D1. The second active pattern AP2 and the second dummy active pattern APD2 may be arranged in the first direction D1.

Although not shown, the first dummy active pattern APD1 and the second dummy active pattern APD2 may be in contact with the dummy bit line BL.

The second active pattern AP2 and the second dummy active pattern APD2 will be described as an example. The length of the second active pattern AP2 in the first direction D1 may be the same as the length of the second dummy active pattern APD2 in the first direction length D1. Unlike the shown example, the length of the second active pattern AP2 in the first direction D1 may be shorter than the length of the second dummy active pattern APD2 in the first direction D1.

Although the first dummy active pattern APD1 and the second dummy active pattern APD2 are shown as not being connected to the data storage pattern DSP, the example embodiments are not limited thereto. Unlike the shown example, the first dummy active pattern APD1 and the second dummy active pattern APD2 may be connected to the data storage pattern DSP.

The description of the first dummy active pattern APD1 and the second dummy active pattern APD2 may be substantially the same as the description of the first active pattern AP1 and the second active pattern AP2.

For example, the first shielding conductive plate SLh_1 may not overlap the first active patterns AP1 and the second active patterns AP2 in the third direction D3. The first shielding conductive plate SLh_1 may not overlap the first dummy active patterns APD1 and the second dummy active patterns APD2 in the third direction.

Unlike the shown example, the first shielding conductive plate SLh_1 may overlap the first active pattern AP1 and the first dummy active pattern APD1 disposed at a boundary portion of the cell array region CAR in the third direction D3.

The back gate electrodes BG may be disposed on the bit line BL and the shielding conductive pattern SL. The back gate electrodes BG may be disposed on the dummy bit line BL_D.

The back gate electrodes BG may be spaced apart from each other in the second direction D2. The back gate electrodes BG may be spaced apart at regular intervals. Each back gate electrode BG may extend in the first direction D1 across the bit line BL.

Each back gate electrode BG may be disposed between the first active pattern AP1 and the second active pattern AP2 that are adjacent to each other in the second direction D2. The first active pattern AP1 and the second active pattern AP2 may be spaced apart from each other in the second direction D2 with the back gate electrode BG interposed between them. That is to say, the first active pattern AP1 may be disposed on one side of each back gate electrode BG, and the second active pattern AP2 may be disposed on the other side of each back gate electrode BG. The height of the back gate electrode BG in the third direction D3 may be smaller than the heights of the first and second active patterns AP1 and AP2.

Each back gate electrode BG may be disposed between the first side wall SS1 of the first active pattern AP1 and the second side wall SS2 of the second active pattern AP2. Each back gate electrode BG may be disposed on the first side wall SS1 of the first active pattern AP1 and the second side wall SS2 of the second active pattern AP2.

The first active pattern AP1 may be disposed between the first word line WL1 and the back gate electrode BG. The second active pattern AP2 may be disposed between the second word line WL2 and the back gate electrode BG. A pair of first word lines WL1 and second word lines WL2 may be disposed between the back gate electrodes BG adjacent to each other in the second direction D2.

The first dummy active pattern APD1 may be disposed between the first word line WL1 and the back gate electrode BG. The second dummy active pattern APD2 may be disposed between the second word line WL2 and the back gate electrode BG.

The back gate electrode BG may include a first surface BG_S1 and a second surface BG_S2 that are opposite to each other in the third direction D3. The first surface BG_S1 of the back gate electrode is closer to the bit line BL than the second surface BG_S2 of the back gate electrode. The first surface BG_S1 of the back gate electrode may look at the bit line BL.

The back gate electrode BG includes a conductive material, and may include, for example, at least one of a conductive semiconductor material, conductive metal nitride, conductive metal silicon nitride, metal carbonitride, conductive metal silicide, conductive metal oxide, two-dimensional materials, and/or metals.

A voltage is applied to the back gate electrode BG at the time of operation of the semiconductor memory device, and a threshold voltage of the vertical channel transistor may be adjusted. Since the threshold voltage of the vertical channel transistor is adjusted, leakage current characteristics may be prevented or reduced from deteriorating.

A back gate isolation pattern 111 may be disposed between the first active pattern AP1 and the second active pattern AP2 that are adjacent to each other in the second direction D2. The back gate isolation pattern 111 may extend in the first direction D1 along with the back gate electrode BG. The back gate isolation pattern 111 may be disposed on the second surface BG_S2 of the back gate electrode.

The back gate isolation pattern 111 may include, for example, a silicon oxide film, a silicon oxynitride film or a silicon nitride film. The back gate isolation pattern 111 may be formed at the same level as a gate capping pattern 143, which will be described below. Here, “the same level” means that they are formed by the same manufacturing process. The back gate isolation pattern 111 may be formed of the same material as the gate capping pattern 143.

A back gate insulating pattern 113 may be disposed between the back gate electrode BG and the first active pattern AP1, and between the back gate electrode BG and the second active pattern AP2. The back gate insulating pattern 113 may be disposed between the back gate isolation pattern 111 and the first active pattern AP1, and between the back gate isolation pattern 111 and the second active pattern AP2. The back gate insulating pattern 113 may include, for example, a silicon oxide film, a silicon oxynitride film, a high dielectric constant insulating film having a higher dielectric constant than a silicon oxide film, or a combination thereof.

A back gate capping pattern 115 may be disposed between the bit line BL and the back gate electrode BG. The back gate capping pattern 115 may be disposed between the first active pattern AP1 and the second active pattern AP2 that are adjacent to each other in the second direction D2. The back gate capping pattern 115 may extend in the first direction D1 along with the back gate electrode BG. The back gate capping pattern 115 may be disposed on the first surface BG_S1 of the back gate electrode.

The back gate capping pattern 115 may be made of an insulating material. The back gate capping pattern 115 may include, for example, at least one of a silicon oxide film, a silicon oxynitride film, and/or a silicon nitride film.

An active pattern isolation structure APBK may be disposed on both sides of the back gate electrode BG in the first direction D1. Each back gate electrode BG may be disposed between the active pattern isolation structures APBK spaced apart in the first direction D1. The active pattern isolation structures APBK spaced apart in the first direction D1 may be aligned with each back gate electrode BG in the first direction D1. The active pattern isolation structure APBK may be spaced apart from the cell region element isolation film STI.

The active pattern isolation structure APBK may be formed of an insulating material. Depending on the materials included in the active pattern isolation structure APBK and the back gate insulating pattern 113, a boundary between the active pattern isolation structure APBK and back gate insulating pattern 113 may not be distinguished. Additionally, depending on the materials included in the active pattern isolation structure APBK and the gate isolation pattern GSS, a boundary between the active pattern isolation structure APBK and the gate isolation pattern GSS may not be distinguished.

The first word line WL1 and the second word line WL2 may be disposed on the bit line BL, the dummy bit line BL_D, and the shielding conductive pattern SL. The first word line WL1 and the second word line WL2 may be disposed on the shielding conductive line pattern SLp.

Each of the first word line WL1 and the second word line WL2 may extend in the first direction D1. The first word line WL1 and the second word line WL2 may be alternately arranged in the second direction D2.

The first word line WL1 may be disposed on the second side walls SS2 of the first active patterns AP1. The second word line WL2 may be disposed on the first side walls SS1 of the second active patterns AP2. The first active patterns AP1 and the second active patterns AP2 may be disposed between the first word line WL1 and the second word line WL2 adjacent to each other in the second direction D2. The first dummy active pattern APD1 and the second dummy active pattern APD2 may be disposed between the first word line WL1 and the second word line WL2 adjacent to each other in the second direction D2.

Each of the first word line WL1 and the second word line WL2 may extend along the side wall of the active pattern isolation structure APBK.

The first word line WL1 and the second word line WL2 may be spaced apart from the bit line BL and the contact pattern BC in the third direction D3. The first word line WL1 and the second word line WL2 may be located between the bit line BL and the contact pattern BC.

Each of the first word line WL1 and the second word line WL2 may have widths in the second direction D2. The width of the first word line WL1 and the width of the second word line WL2 on the bit line BL may be different from the width of the first word line WL1 and the width of the second word line WL2 on the shielding conductive pattern SL.

For example, each of the first word line WL1 and the second word line WL2 may include a first portion WLa of the word line and a second portion WLb of the word line. The width of the first portion WLa of the word line in the second direction D2 may be smaller than the width of the second portion WLb of the word line in the second direction D2. As an example, the first portion WLa of the word line may overlap the bit line BL in the third direction D3.

The second portion WLb of the word line may overlap the shielding conductive line SL in the third direction D3.

Each of the first word line WL1 and the second word line WL2 may include the first portion WLa of the word line and the second portion WLb of the word line which are alternately disposed along the first direction D1. In the first word line WL1, each first active pattern AP1 may be disposed between the second portions WLb of word lines adjacent in the first direction D1. In the second word line WL2, each second active pattern AP2 may be disposed between the second portions WLb of word lines adjacent in the first direction D1.

The first word line WL1 and the second word line WL2 may include a first surface WL_S1 and a second surface WL_S2 that are opposite to each other in the third direction D3. The first surface WL_S1 of the first and second word lines is closer to the bit line BL than the second surface WL_S2 of the first and second word lines.

The first word line WL1 will be explained as an example. As an example, a height of the first word line WL1 in the third direction D3 may be equal to a height of the back gate electrode BG in the third direction D3. As another example, a height of the first word line WL1 in the third direction D3 may be greater than a height of the back gate electrode BG in the third direction D3. As yet another example, the height of the first word line WL1 in the third direction D3 may be smaller than the height of the back gate electrode BG in the third direction D3.

Further, as an example, the height of the first surface WL_S1 of the first word line may be equal to the height of the first surface BG_S1 of the back gate electrode, on the basis of the upper surface BL_US of the bit line. As another example, the first surface WL_S1 of the first word line may be higher than the first surface BG_S1 of the back gate electrode. As yet another example, the first surface WL_S1 of the first word line may be lower than the first surface BG_S1 of the back gate electrode. For example, the semiconductor pattern 161 may include an upper surface BL_US of the bit line. When the bit line BL does not include the semiconductor pattern 161, the metal pattern 163 may include the upper surface BL_US of the bit line.

In addition, as an example, the height of the second surface WL_S2 of the first word line may be equal to the height of the second surface BG_S2 of the back gate electrode, on the basis of the upper surface BL_US of the bit line. As another example, the second surface WL_S2 of the first word line may be higher than the second surface BG_S2 of the back gate electrode. As yet another example, the second surface WL_S2 of the first word line may be lower than the second surface BG_S2 of the back gate electrode.

The first word line WL1 and the second word line WL2 include a conductive material. The first word line WL1 and the second word line WL2 may include, for example, at least one of a conductive semiconductor material, a conductive metal nitride, a conductive metal silicon nitride, a metal carbonitride, a conductive metal silicide, a conductive metal oxide, a two-dimensional material, and/or a metal. Although the first word line WL1 and the second word line WL2 are shown as being a single conductive film, this is only for convenience of explanation and the example embodiments are not limited thereto.

The first surfaces WL_S1 of the first and second word lines WL1 and WL2 may be a plane. Unlike the shown example, as an example, the first surfaces WL_S1 of the first and second word lines WL1 and WL2 may be concavely rounded. As another example, each of the first word line WL1 and the second word line WL2 may have the form of a spacer. In other words, the first surfaces WL_S1 of the first and second word lines WL1 and WL2 may be convexly rounded.

The second surfaces WL_S2 of the first and second word lines WL1 and WL2 may be a plane. Unlike the shown example, the second surfaces WL_S2 of the first and second word lines WL1 and WL2 may have a concave curved face. Although the first surface BG_S1 of the back gate electrode and the second surface BG_S2 of the back gate electrode are shown as a being a plane, the example embodiments are not limited thereto.

The dummy word line WL_D may extend along the boundary of the cell array region CAR. For example, the dummy word line WL_D may extend in the first direction D1. The dummy word line WL_D may not extend in the second direction D2. The dummy word line WL_D may extend along the first cell region side wall STI_S1 of the cell region element isolation film STI. The dummy word line WL_D may not extend along the second cell region side wall STI_S2 of the cell region element isolation film STI. The dummy word line WL_D may be spaced apart from the first and second word lines WL1 and WL2 in the second direction D2.

The gate insulating pattern GOX may be disposed between the first word line WL1 and the first active pattern AP1, and between the second word line WL2 and the second active pattern AP2. The gate insulating pattern GOX may be disposed between the first word line WL1 and the first dummy active pattern APD1, and between the second word line WL2 and the second dummy active pattern APD2. The gate insulating pattern GOX may be disposed between the first word line WL1 and the active pattern isolation structure APBK, and between the second word line WL2 and the active pattern isolation structure APBK. The gate insulating pattern GOX may be disposed between the dummy word line WL_D and the cell region element isolation film STI.

The gate insulating pattern GOX may include a silicon oxide film, a silicon oxynitride film, a high dielectric constant insulating film having a higher dielectric constant than a silicon oxide film, or a combination thereof.

The gate insulating pattern GOX may extend along the second side wall SS2 of the first active pattern AP1, and may extend along the first side wall SS1 of the second active pattern AP2. In the semiconductor memory device according to some example embodiments, from viewpoint of a cross-sectional view, the gate insulating pattern GOX between the first active pattern AP1 and the first word line WL1 may be separated from the gate insulating pattern GOX between the second active pattern AP2 and the second word line WL2.

The gate capping pattern 143 may be disposed between the first word line WL1 and the contact pattern BC, and between the second word line WL2 and the contact pattern BC. The gate capping pattern 143 may cover the second surface WL_S2 of the first and second word lines WL1 and WL2.

The gate separation pattern GSS may be disposed on the bit line BL. The gate separation pattern GSS may be disposed on the bit line BL. The gate isolation pattern GSS may be disposed on the dummy bit line BL_D. The gate separation pattern GSS may be disposed between the bit line BL and the contact pattern BC. The gate separation pattern GSS may be in contact with the bit line BL.

The gate separation pattern GSS may be disposed between the first word line WL1 and the second word line WL2 adjacent to each other in the second direction D2. The first word line WL1 and the second word line WL2 may be separated by the gate isolation pattern GSS. The gate separation pattern GSS may extend in the first direction D1 between the first word line WL1 and the second word line WL2. The gate isolation pattern GSS may be disposed between the cell region element isolation film STI and the active pattern isolation structure APBK.

The first word line WL1 may be disposed between the gate isolation pattern GSS and the first active pattern AP1. The second word line WL2 may be disposed between the gate isolation pattern GSS and the second active pattern AP2.

The gate separation pattern GSS may include a horizontal part GSS_H and a protruding part GSS_P. The protruding part GSS_P of the gate isolation pattern may protrude from the horizontal part GSS_H of the gate isolation pattern in the third direction D3.

The horizontal part GSS_H of the gate isolation pattern may be closer to the bit line BL than the protruding part GSS_P of the gate isolation pattern. The horizontal part GSS_H of the gate isolation pattern may be in contact with the bit line BL. The width of the horizontal part GSS_H of the gate isolation pattern in the second direction D2 is greater than the width of the protruding part GSS_P of the gate isolation pattern in the second direction D2.

The protruding part GSS_P of the gate isolation pattern may be disposed between the side walls of the first word line WL1 and the second word line WL2 that face each other. The horizontal part GSS_H of the gate separation pattern may cover the first surfaces WL_S1 of the first and second word lines WL1 and WL2.

The first word line WL1 and the second word line WL2 may be disposed on the horizontal part GSS_H of the gate separation pattern. The first word line WL1 and the second word line WL2 may have a shape that sits on the horizontal part GSS_H of the gate separation pattern. The first word line WL1 and the second word line WL2 may be disposed between the horizontal part GSS_H of the gate isolation pattern and the contact pattern BC in the third direction D3.

The gate separation pattern GSS may be made of an insulating material. Unlike the shown example, the gate isolation pattern GSS may include a plurality of insulating films.

The contact patterns BC may penetrate the contact interlayer insulating film 231. The contact patterns BC may be connected to each of the first active pattern AP1 and the second active pattern AP2. The contact patterns BC may be connected to the second surfaces S2 of the first and second active patterns AP1 and AP2. From viewpoint of a plan view, each contact pattern BC may have various shapes such as a circle, an ellipse, a rectangle, a square, a rhombus, and a hexagon. The contact interlayer insulating film 231 may be disposed on the cell region element isolation film STI.

The contact patterns BC may not be connected to the first and second dummy active patterns APD1 and APD2. Unlike the shown example, the contact patterns BC may be connected to the first and second dummy active patterns APD1 and APD2.

The contact pattern BC may include a conductive material. The contact pattern BC may include, for example, at least one of a conductive semiconductor material, a conductive metal nitride, a conductive metal silicon nitride, a metal carbonitride, a conductive metal silicide, a conductive metal oxide, a two-dimensional material, and/or a metal. The contact interlayer insulating film 231 includes an insulating material.

The landing pads LP may be disposed on the contact pattern BC. From viewpoint of a plan view, the landing pads LP may have various shapes, such as a circle, an ellipse, a rectangle, a square, a rhombus, and a hexagon.

A pad isolation insulating film 245 may be disposed on the contact interlayer insulating film 231. The pad isolation insulating film 245 may be disposed between the landing pads LP. The pad isolation insulating film 245 may isolate the landing pads LP. From viewpoint of a plan view, the landing pads LP may be arranged in the form of a matrix along the first direction D1 and the second direction D2. The upper surface of the landing pad LP may be substantially coplanar with the upper surface of the pad isolation insulating film 245.

The landing pad LP includes a conductive material, and may include, for example, at least one of a conductive semiconductor material, a conductive metal nitride, a conductive metal silicon nitride, a metal carbonitride, a conductive metal silicide, a conductive metal oxide, a two-dimensional material, and/or a metal. The pad isolation insulating film 245 includes an insulating material.

The bit line contact plug 281a may be connected to the bit line BL. The bit line contact plug 281a may be disposed inside the contact interlayer insulating film 231 and the cell region element isolation film STI. The bit line contact plug 281a is connected to the conductive bit line.

Although not shown, a word line contact plug connected to the first and second word lines WL1 and WL2 may be disposed.

An upper connecting wiring 282a may be disposed inside the pad isolation insulating film 245. The upper connecting wiring 282a may be connected to the bit line contact plug 281a.

The upper peripheral contact plug 283a may be connected to the peri-connecting wiring 242b. The upper peripheral contact plug 283a may penetrate the contact interlayer insulating film 231, the cell region element isolation film STI, and the first upper insulating film 263. The upper peripheral contact plug 283a may connect the bit line BL and the peri-connecting wiring 242b.

Each of the bit line contact plug 281a, the upper connecting wiring 282a, and the upper peripheral contact plug 283a includes a conductive material.

Data storage patterns DSP may be disposed on the landing pads LP, respectively. The data storage patterns DSP may be electrically connected to each of the first and second active patterns AP1 and AP2. The data storage patterns DSP may be arranged in the form of a matrix along the first direction D1 and the second direction D2, as shown in FIG. 2. The data storage patterns DSP may completely or partially overlap the landing pads LP in the third direction D3. The data storage patterns DSP may be in contact with all or part of the upper surfaces of the landing pads LP.

As an example, the data storage patterns DSP may be capacitors. The data storage patterns DSP may include a capacitor dielectric film 253 interposed between the storage electrodes 251 and the plate electrode 255. The storage electrode 251 may be in contact with the landing pad LP. From viewpoint of a plan view, the storage electrode 251 may have various shapes such as a circle, an ellipse, a rectangle, a square, a rhombus, and a hexagon. The storage electrodes 251 may penetrate an upper etching stop film 247. The upper etching stop film 247 may be disposed on the pad isolation insulating film 245. The upper etching stop film 247 may be made of an insulating material.

The plate electrode 255 may include a lower plate electrode 255a and an upper plate electrode 255b. Unlike the shown example, the plate electrode 255 may be a single film. The storage electrode 251 and the plate electrode 255 may each include, for example, at least one of a conductive semiconductor material, a conductive metal nitride, a conductive metal silicon nitride, a metal carbonitride, a conductive metal silicide, a conductive metal oxide, and a metal. The capacitor dielectric film 253 may include at least one of a ferroelectric material, an antiferroelectric material, and a paraelectric material. For example, the capacitor dielectric film 253 may include one of the ferroelectric material, the antiferroelectric material, the paraelectric material, a combination of the ferroelectric material and the antiferroelectric material, a combination of the ferroelectric material and the paraelectric material, a combination of the paraelectric material and antiferroelectric material, and a combination of the ferroelectric material, the antiferroelectric material, and the paraelectric material.

In contrast, the data storage patterns DSP may be variable resistances pattern that may be switched between two resistance states by an electrical pulse applied to the memory element.

For example, the data storage patterns DSP may include a phase-change material whose crystal state changes depending on the amount of current, perovskite compounds, transition metal oxide, magnetic materials, ferromagnetic materials or antiferromagnetic materials.

The second upper insulating film 271 may be disposed on the upper etching stop film 247. The second upper insulating film 271 may be disposed on the data storage pattern DSP. For example, the second upper insulating film 271 may cover the data storage patterns DSP. The second upper insulating film 271 may wrap around the side walls of the plate electrode 255. The second upper insulating film 271 includes an insulating material.

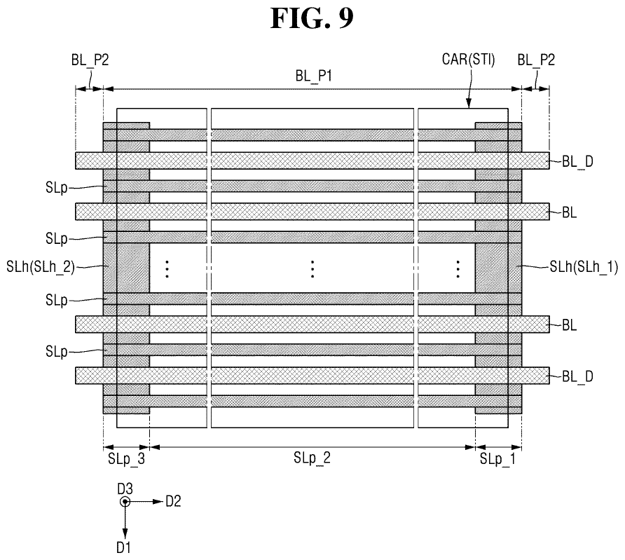

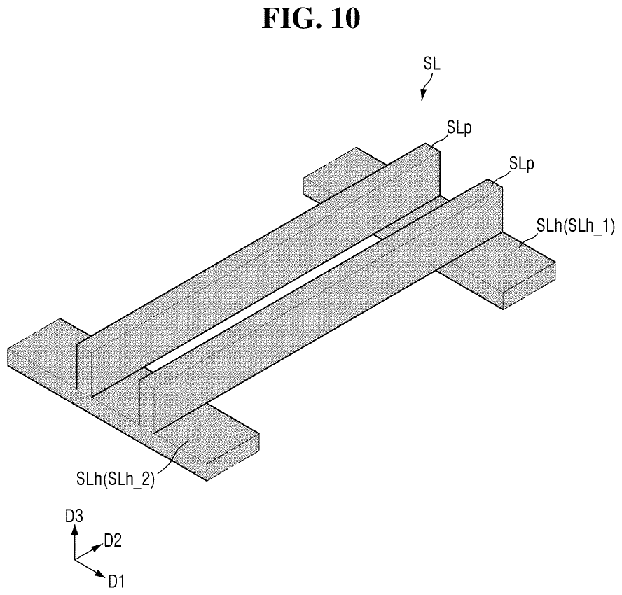

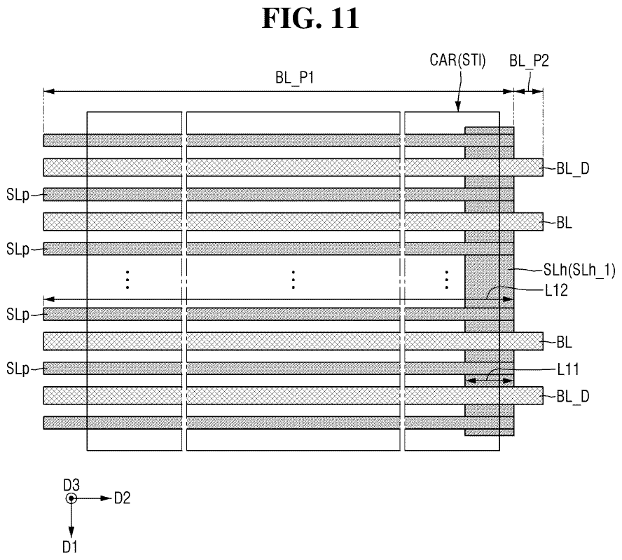

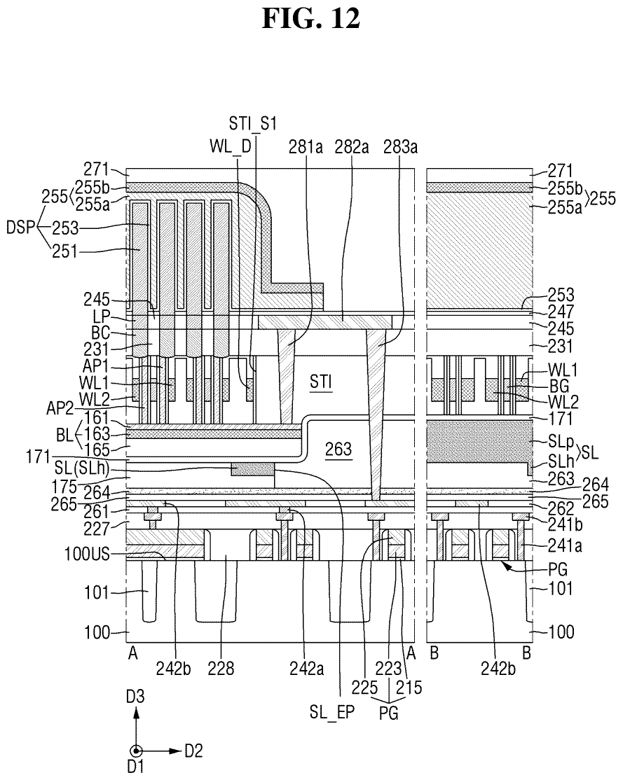

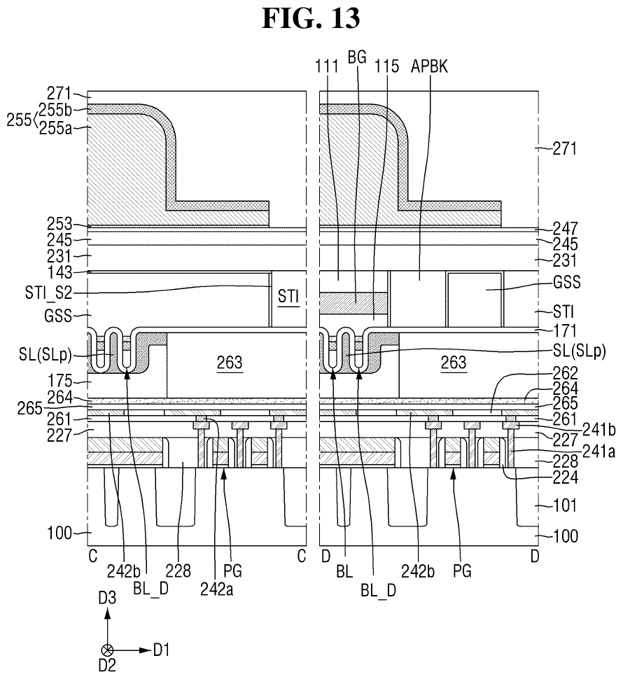

FIGS. 9 and 10 are diagrams for explaining a semiconductor memory device according to some example embodiments. FIG. 11 is a diagram for explaining the semiconductor memory device according to some example embodiments. FIGS. 12 and 13 are diagrams for explaining the semiconductor memory device according to some example embodiments. For convenience of explanation, the explanation will focus on the points that are different from those explained using FIGS. 1 to 8.

Referring to FIGS. 9 and 10, in the semiconductor memory device according to some example embodiments, the shielding conductive pattern SL may further include a second shielding conductive plate SLh_2.

The shielding conductive plate SLh may include a first shielding conductive plate SLh_1 and a second shielding conductive plate SLh_2. The second shielding conductive plate SLh_2 is spaced apart from the first shielding conductive plate SLh_1 in the second direction D2.

The second shielding conductive plate SLh_2 may have a flat plate shape. The second shielding conductive plate SLh_2 may be disposed on the cell array region CAR. A part of the second shielding conductive plate SLh_2 may be placed over the peripheral circuit region PCR, but the example embodiment is not limited thereto.

The plurality of shielding conductive line patterns SLp may protrude from the second shielding conductive plate SLh_2 in the third direction D3. The shielding conductive line pattern SLp is connected, for example directly connected, to the second shielding conductive plate SLh_2.

Another part of the shielding conductive line pattern SLp may overlap the second shielding conductive plate SLh_2 in the third direction D3. A length (L12 of FIG. 7) of the shielding conductive line pattern SLp in the second direction D2 is greater than a length of the second shielding conductive plate SLh_2 in the second direction D2.

Each shielding conductive line pattern SLp may include a first portion SLp_1, a second portion SLp_2, and a third portion SLp_3. The second portion SLp_2 of the shielding conductive line pattern is disposed between the first portion SLp_1 of the shielding conductive line pattern and the third portion SLp_3 of the shielding conductive line pattern.

The third portion SLp_3 of the shielding conductive line pattern may overlap the third shielding conductive plate SLh_3 in the third direction D3. The second portion SLp_2 of the shielding conductive line pattern may not overlap the first shielding conductive plate SLh_1 and the second shielding conductive plate SLh_2 in the third direction D3.

Each bit line BL may be disposed on the first shielding conductive plate SLh_1 and the second shielding conductive plate SLh_2.

When the shielding conductive pattern SL includes the first shielding conductive plate SLh_1 and the second shielding conductive plate SLh_2, the length of the bit line BL in the second direction D2 may be equal to the length (L12 of FIG. 7) of the shielding conductive line pattern SLp in the second direction D2, unlike the shown example.

For example, the second shielding conductive plate SLh_2 may not overlap the first active patterns (AP1 of FIG. 2) and the second active patterns (AP2 of FIG. 2) in the third direction D3. The second shielding conductive plate SLh_2 may not overlap the first dummy active patterns (APD1 of FIG. 2) and the second dummy active patterns (APD2 of FIG. 2) in the third direction.

Referring to FIG. 11, in the semiconductor memory device according to some example embodiments, the second portion BL_P2 of the bit line may be disposed on one side of the first portion BL_P1 of the bit line.

Although the second portion BL_P2 of the bit line is shown to protrude in the second direction D2 beyond the shielding conductive line pattern SLp, in the vicinity of the region in which the first shielding conductive plate SLh_1 is located, the example embodiment is not limited thereto. Unlike the shown example, the second portion BL_P2 of the bit line may protrude in the second direction D2 beyond the shielding conductive line pattern SLp, in the vicinity of the region in which the first shielding conductive plate SLh_1 is not located.

Referring to FIGS. 12 and 13, the semiconductor memory device according to some example embodiments may further include a bonding insulating film 264 disposed between the peri-connecting structures 242a and 242b and the first upper insulating film 263.

For example, the bonding insulating film 264 may be disposed between the first upper insulating film 263 and the third peri-upper insulating film 265. The bonding insulating film 264 may be disposed between the shielding insulation capping film 175 and the third peri-upper insulating film 265. The bonding insulating film 264 may include, for example, silicon carbonitride (SiCN).

Unlike the shown example, the third peri-upper insulating film 265 may not be disposed on the peri-connecting wiring 242b.

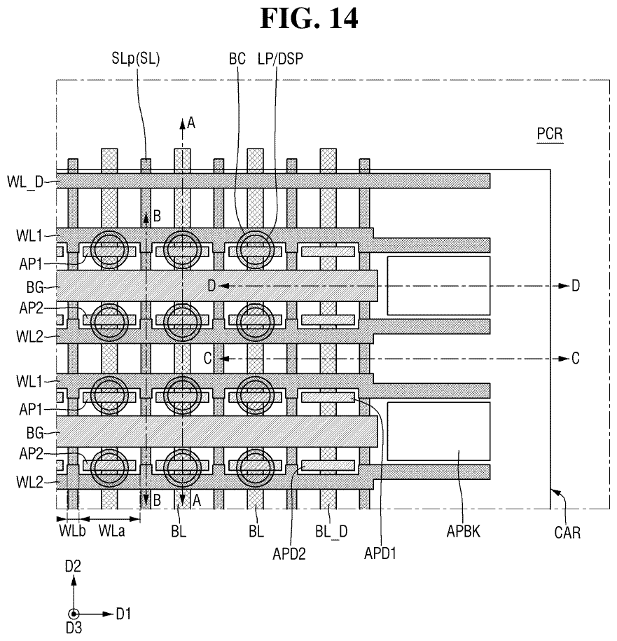

FIGS. 14 to 18 are diagrams for explaining a semiconductor memory device according to some example embodiments. For convenience of explanation, the explanation will focus on the points that are different from those explained using FIGS. 1 to 8.

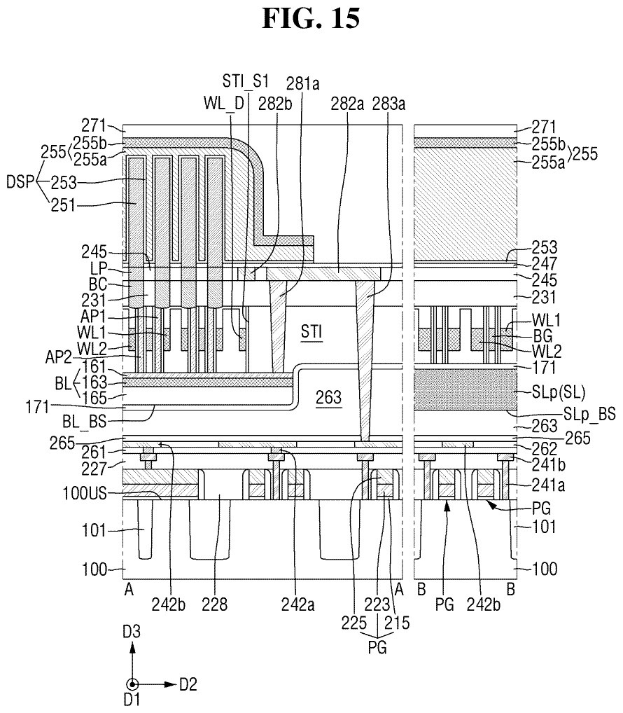

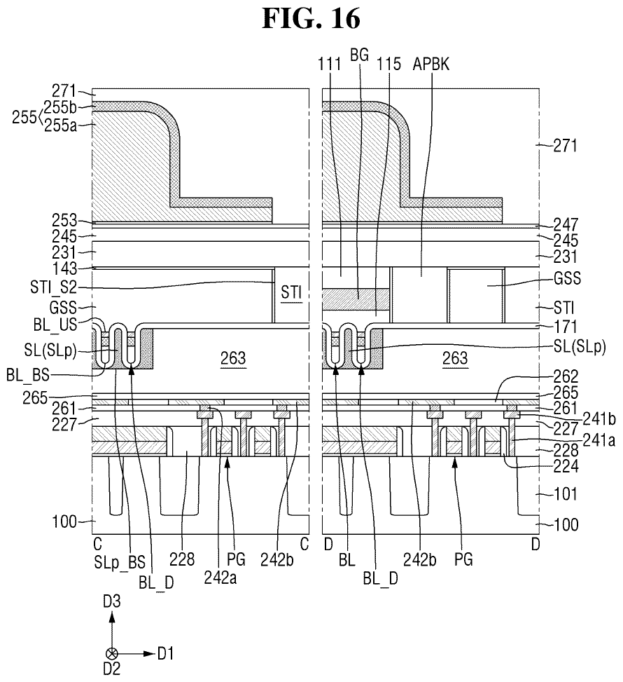

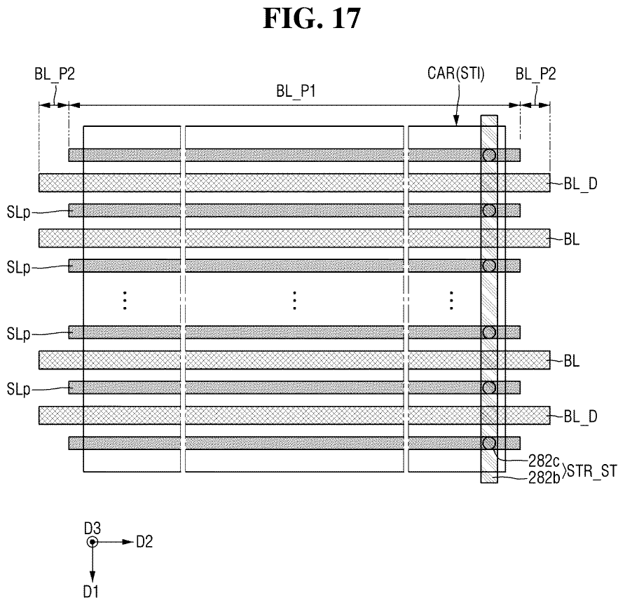

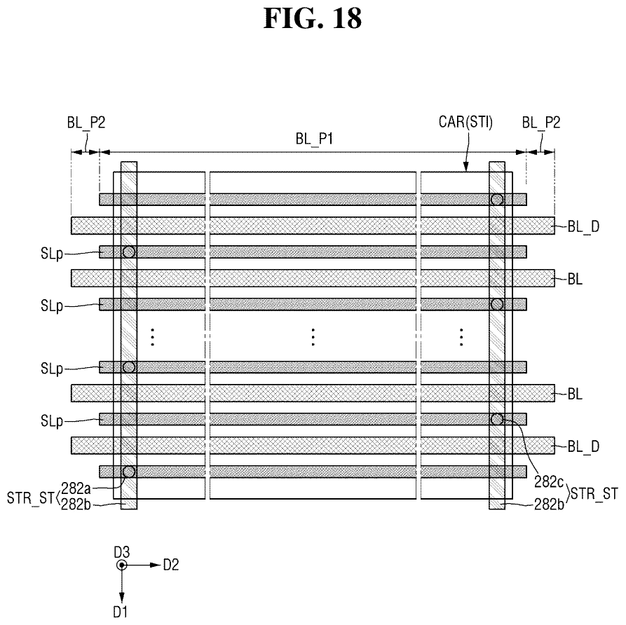

For reference, FIG. 14 is a layout diagram of a boundary portion between the cell array region and the peripheral circuit region of FIG. 1. FIG. 15 is a cross-sectional view taken along lines A-A and B-B of FIG. 14. FIG. 16 is a cross-sectional view taken along lines CC and D-D of FIG. 14. FIGS. 17 and 18 are diagrams for explaining a connection relationship between the shielding conductive pattern and the shielding strap line, respectively.

Referring to FIGS. 14 to 18, in the semiconductor memory device according to some example embodiments, the shielding conductive pattern SL does not include a shielding conductive plate (SLh of FIG. 2) having a flat plate shape.

The bit line BL may include an upper surface BL_US and a bottom surface BL_BS that are opposite to each other in the third direction D3. The upper surface BL_US of the bit line may look at the first active pattern AP1 and the second active pattern AP2. The bottom surface BL_BS of the bit line may look at the peri-gate structure PG.

The shielding conductive pattern SL is not disposed on the bottom surface BL_BS of the bit line. The shielding conductive pattern SL may include a plurality of shielding conductive line patterns SLp without the shielding conductive plate SLh. A first shielding conductive plate SLh_1 and/or a second shielding conductive plate SLh_2 are not disposed between the shielding conductive line pattern SLp and the peri-gate structure PG.

The shielding conductive line pattern SLp may include a bottom surface SLp_BS that looks at (e.g. faces) the peri-gate structure PG. For example, on the basis of the upper surface 100US of the substrate, the bottom surface BL_BS of the bit line may be higher than the bottom surface SLp_BS of the shielding conductive line pattern. In other words, the depth from the upper surface BL_US of the bit line to the bottom surface BL_BS of the bit line may be smaller than the depth from the upper surface BL_US of the bit line to the bottom surface SLp_BS of the shielding conductive line pattern.

Each bit line BL includes a first portion BL_P1 of the bit line and a second portion BL_P2 of the bit line. Although the second portion of the bit line BL_P2 is shown as being disposed on either side of the first portion of the bit line BL_P1, the example embodiments are not limited thereto. Unlike the shown example, the second portion BL_P2 of the bit line may be disposed on one side of the first portion BL_P1 of the bit line.

In the semiconductor memory device according to some example embodiments, the shielding insulation capping film (175 of FIGS. 3 and 4) may not be disposed between the shielding conductive pattern SL and the peri-connecting structures 242a and 242b. The first upper insulating film 263 may cover the bottom surface SLp_BS of the shielding conductive line pattern.

The shielding strap structure STR_ST may be disposed on the shielding conductive pattern SL. The shielding strap structure STR_ST may be electrically connected to the shielding conductive pattern SL. For example, the shielding strap structure STR_ST may be connected to the shielding conductive line pattern SLp.

The shielding strap structure STR_ST may include a plurality of shielding strap vias 282c and a shielding strap line 282b. The shielding strap via 282c may be connected to the shielding conductive line pattern SLp. The shielding strap via 282c may connect the shielding conductive line pattern SLp and the shielding strap line 282b. Although not shown, the shielding strap structure STR_ST may include an upper peripheral contact plug that connects the shielding strap line 282b and the peri-connecting wiring 242b.

The shielding strap line 282b may extend in the first direction D1. The shielding strap line 282b may be disposed on the inner the cell array region CAR with respect to the upper connecting wiring 282a. The shielding strap line 282b may be disposed between the upper connecting wiring 282a and the landing pad LP.

The shielding strap via 282c may be formed while the bit line contact plug 281a is being formed. While the upper connecting wiring 282a is being formed, the shielding strap line 282b may be formed.

The shielding strap via 282c and the shielding strap line 282b each include a conductive material.

The shielding conductive line pattern SLp may include a first shielding conductive line pattern SLp and a second shielding conductive line pattern SLp that are adjacent, for example directly adjacent, to each other in the first direction D1. The first shielding conductive line pattern SLp and the second shielding conductive line pattern SLp may be connected to one shielding strap via 282c.

In FIG. 17, the shielding strap vias 282c connected to the first shielding conductive line pattern SLp and the shielding strap vias 282c connected to the second shielding conductive line pattern SLp may be aligned in the first direction D1. One shielding strap line 282b may be connected to the entire shielding conductive line pattern SLp.

Although it is shown that there is one shielding strap line 282b connected to the shielding conductive line pattern SLp, the example embodiments are not limited thereto. Unlike the shown example, a plurality of shielding strap lines 282b may be disposed on both sides of the cell array region CAR. In such a case, each shielding strap line 282b may be connected to the entire back gate electrodes BG disposed in the cell array region CAR.

In FIG. 18, a plurality of shielding strap lines 282b may be disposed on the boundary of both sides of the cell array region CAR. One shielding strap line 282b may be connected to some of the plurality of shielding conductive line patterns SLp. Another shielding strap line 282b may be connected to the remainder of the plurality of shielding conductive line patterns SLp. The shielding strap via 282c may be disposed in zigzags along the boundary of the cell array region CAR.

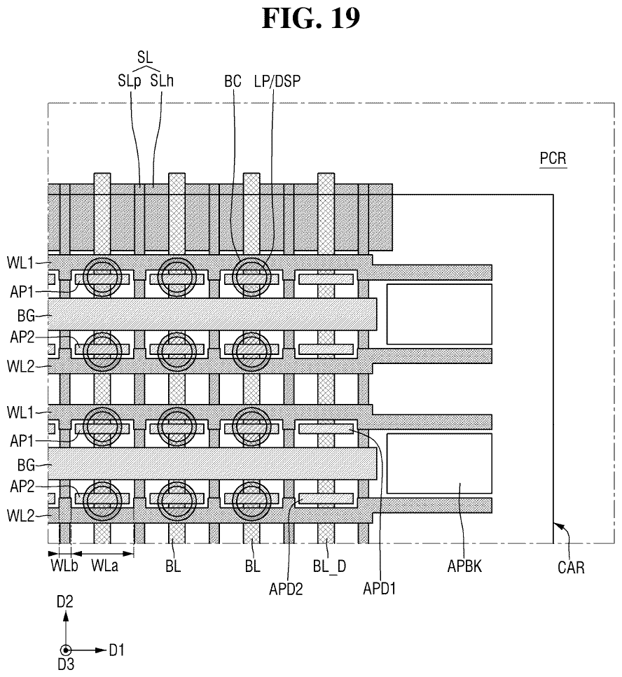

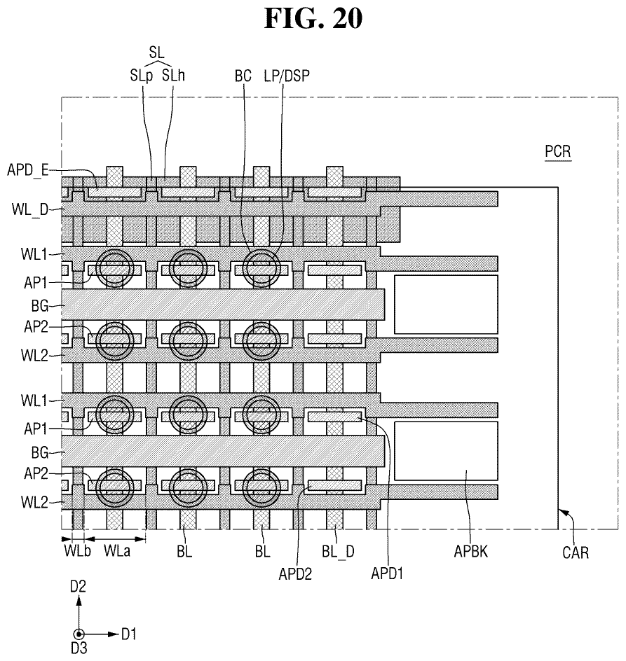

FIGS. 19 and 20 are diagrams for explaining a semiconductor memory device according to some example embodiments, respectively. For convenience of explanation, the explanation will focus on points that are different from those explained using FIGS. 1 to 8.

Referring to FIG. 19, in the semiconductor memory device according to some example embodiments, a dummy word line (WL_D of FIG. 2) may not be disposed along a boundary of the cell array region CAR.

The dummy word line WL_D extending along the first cell region side wall (STI_S1 of FIG. 3) of the cell region element isolation film STI is not disposed inside the cell region element isolation film STI.

Referring to FIG. 20, the semiconductor memory device according to some example embodiments may further include a boundary dummy active pattern APD_E disposed between the dummy word line WL_D and the cell region element isolation film STI.

The boundary dummy active patterns APD_E may be disposed along the boundary of the cell array region CAR. The boundary dummy active patterns APD_E may be disposed along the side wall (STI_S1 of FIG. 3) of the first cell region. For example, the boundary dummy active patterns APD_E may be in contact with the cell region element isolation film STI.

The boundary dummy active patterns APD_E may be spaced apart in the first direction D1. The boundary dummy active patterns APD_E may be arranged in the first direction D1. The boundary dummy active pattern APD_E may not be connected to the data storage pattern DSP.

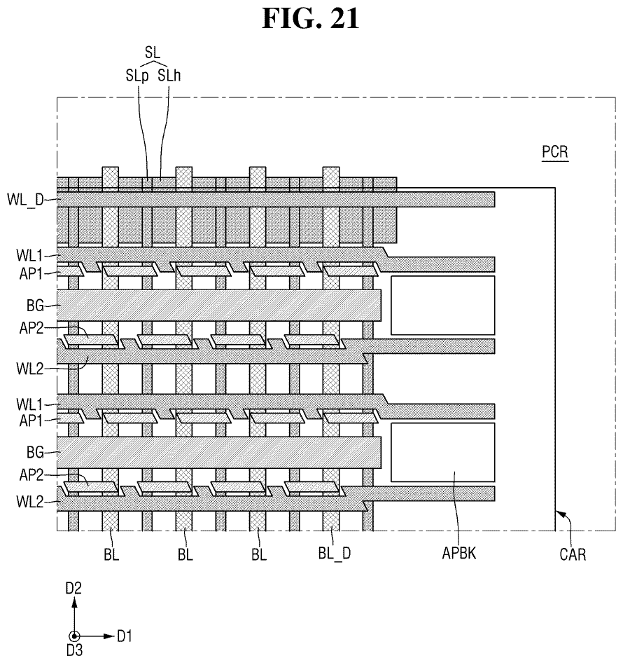

FIGS. 21 to 24 are diagrams for explaining a semiconductor memory device according to some example embodiments, respectively. For convenience of explanation, points different from those described using FIGS. 1 to 20 will be mainly explained.

Referring to FIG. 21, in the semiconductor memory device according to some embodiments, the first and second active patterns AP1 and AP2 may be arranged alternately in a diagonal direction with respect to the first direction D1 and the second direction D2.

From viewpoint of a plan view, each of the first and second active patterns AP1 and AP2 may have a parallelogram or rhombus shape. Since the first and second active patterns AP1 and AP2 are disposed in the diagonal direction, coupling between the first and second active patterns AP1 and AP2 facing each other in the second direction D2 may be reduced.

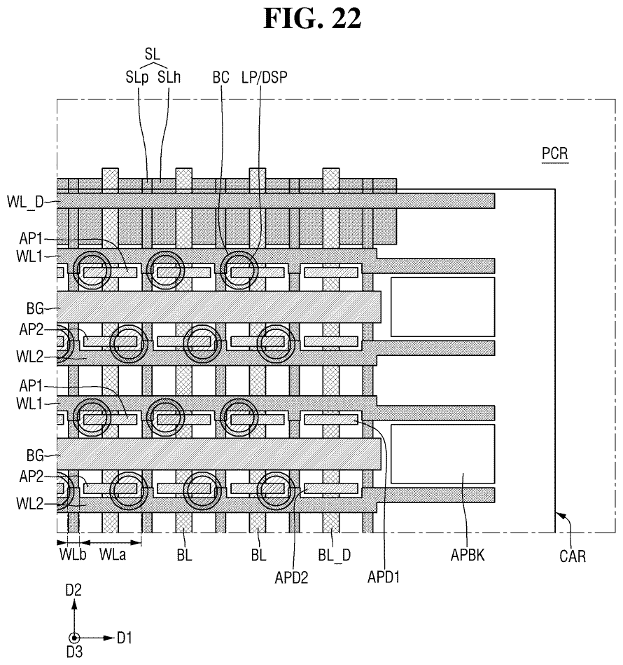

Referring to FIG. 22, in the semiconductor memory device according to some example embodiments, the landing pads LP and the data storage patterns DSP may be arranged in a zigzag or honeycomb form from viewpoint of a plan view.

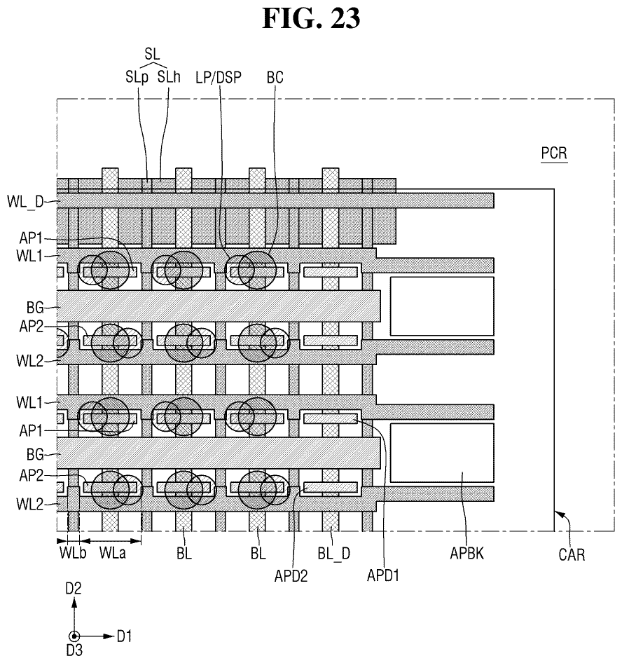

Referring to FIG. 23, in the semiconductor memory device according to some example embodiments, the data storage patterns DSP may be arranged to be offset from the landing pads LP from viewpoint of a plan view.

Each data storage pattern DSP may be in contact with some of the landing pads LP.

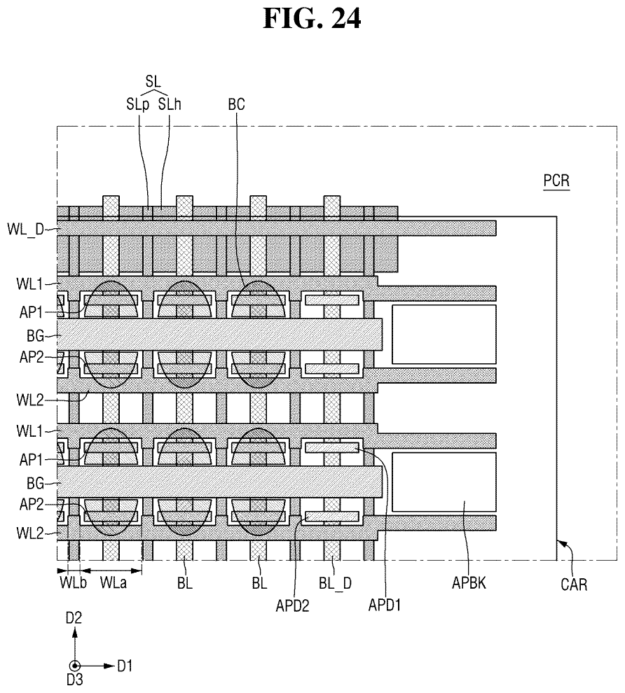

Referring to FIG. 24, in the semiconductor memory device according to some example embodiments, each of the contact patterns BC disposed on the first and second active patterns AP1 and AP2 may have a semicircular form or semi-elliptical shape from viewpoint of a plan view.

The contact patterns BC may be disposed symmetrically with each other with the back gate electrode BG between them from viewpoint of a plan view.

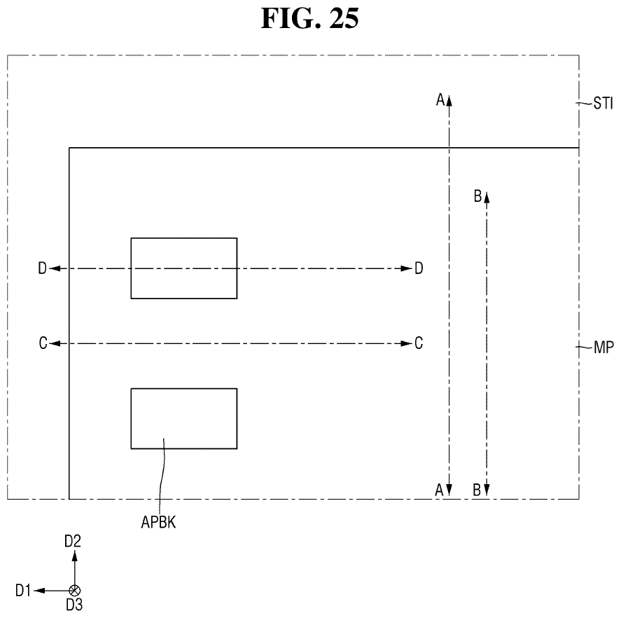

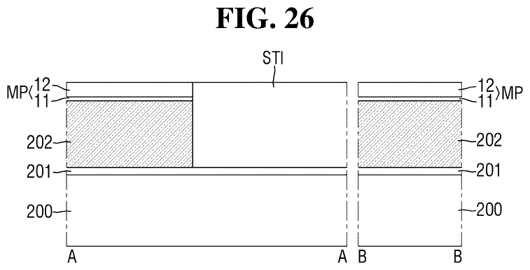

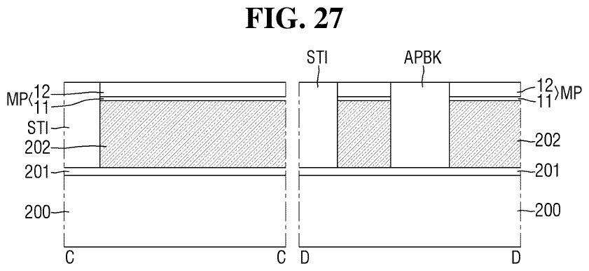

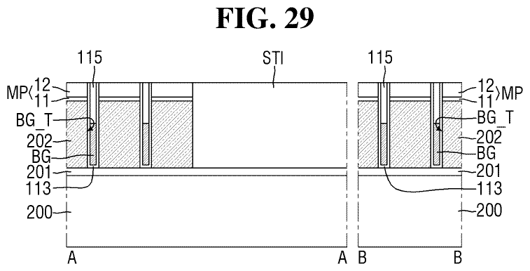

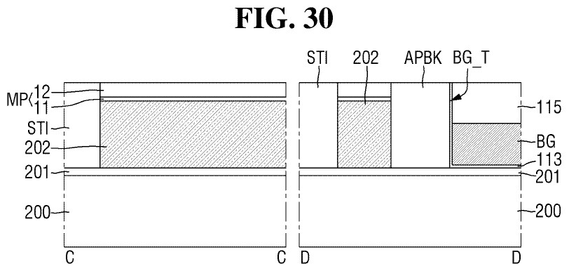

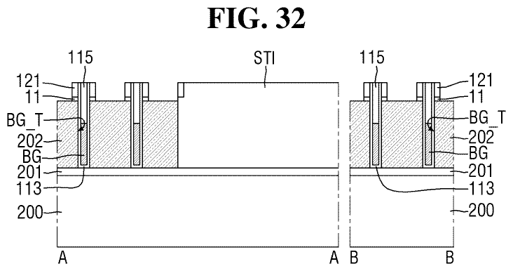

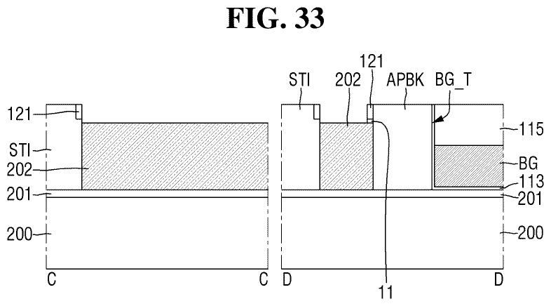

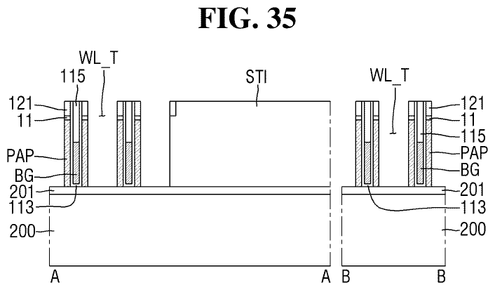

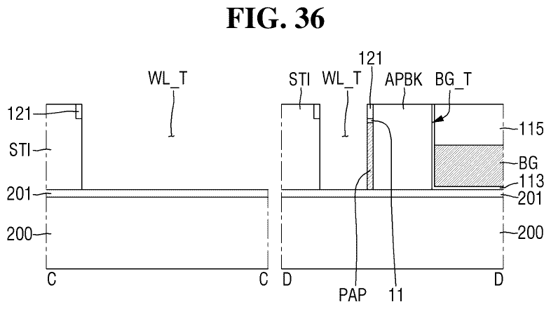

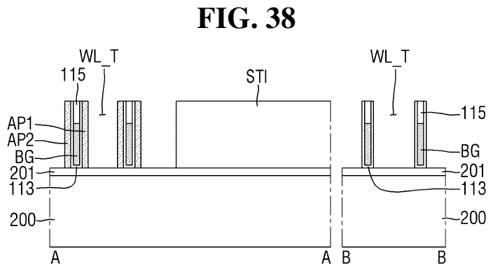

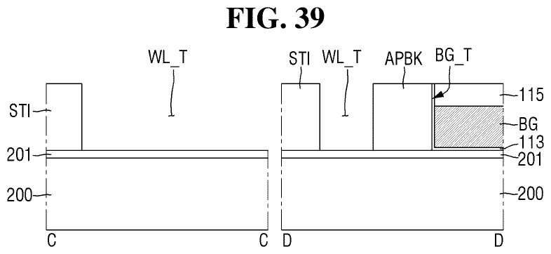

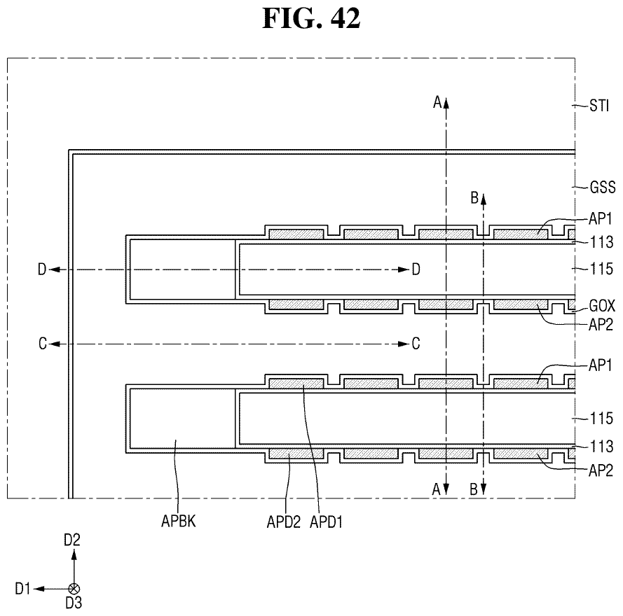

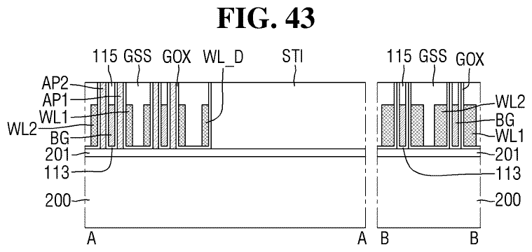

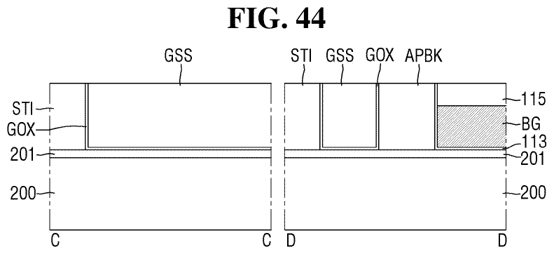

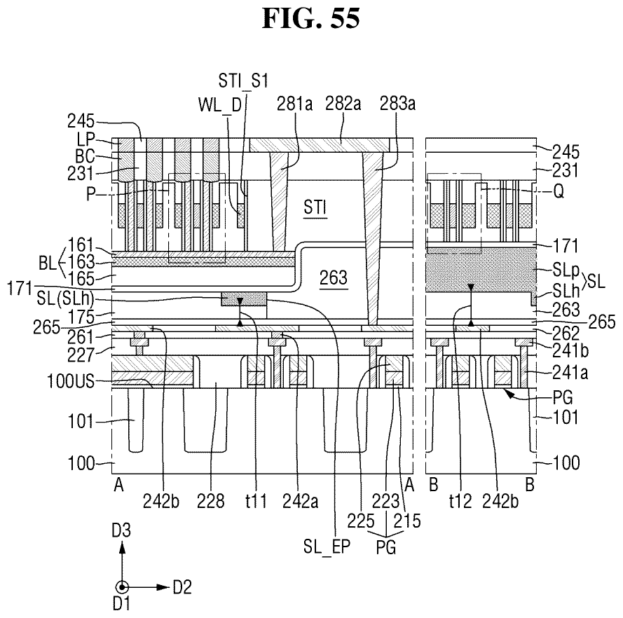

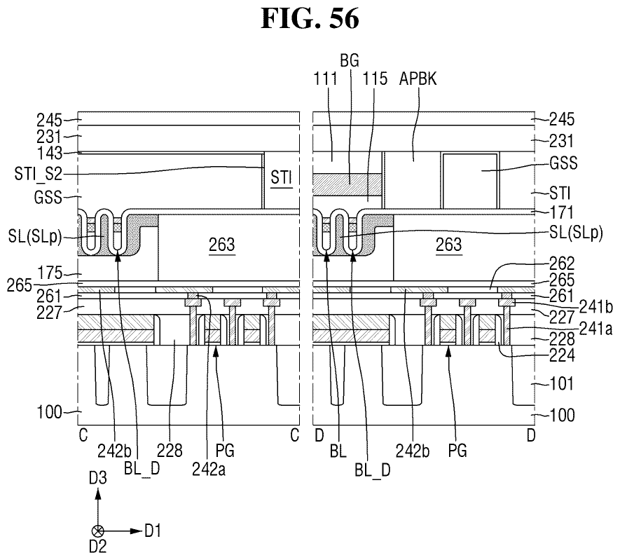

FIGS. 25 to 56 are intermediate stage diagrams for explaining a method for fabricating a semiconductor memory device according to some example embodiments.

Referring to FIGS. 25 to 27, a sub-substrate structure including a sub-substrate 200, a buried insulating layer 201 and an active layer 202 may be provided.

The buried insulating layer 201 and the active layer 202 may be provided on the sub-substrate 200. The sub-substrate 200, the buried insulating layer 201 and the active layer 202 may be a silicon-on-insulator substrate (e.g., an SOI substrate).

The sub-substrate 200 may include a cell array region CAR and a peripheral circuit region PCR. The sub-substrate 200 may be, for example, a silicon substrate, a germanium substrate, and/or a silicon-germanium substrate.

The buried insulating layer 201 may be a buried oxide (BOX) formed by a SIMOX (separation by implanted oxygen) method or a bonding and layer transfer method. In contrast, the buried insulating layer 201 may be an insulating film formed by a chemical vapor deposition method. The buried insulating layer 201 may include, for example, a silicon oxide film, a silicon nitride film, a silicon oxynitride film, and/or a low dielectric constant insulating film.

The active layer 202 may be a single crystal semiconductor film. The active layer 202 may be, for example, a single crystal silicon substrate, a germanium substrate, and/or a silicon-germanium substrate. The active layer 202 may have a first surface and a second surface that are opposite to each other in the third direction D3, and the second surface of the active layer 202 may be in contact with the buried insulating layer 201.

Next, a mask pattern MP may be formed on the active layer 202. The mask pattern MP may include a lower mask film 11 and an upper mask film 12 that are stacked in sequence. The upper mask film 12 may be made of a material that has etching selectivity with respect to the lower mask film 11. As an example, the lower mask film 11 may include silicon oxide, and the upper mask film 12 may include silicon nitride, but the example embodiments are not limited thereto.

Subsequently, the cell region element isolation film STI may be formed inside the active layer 202 of the peripheral circuit region PCR. The cell region element isolation film STI may be formed by patterning the active layer 202 of the peripheral circuit region PCR to form an element isolation trench for exposing the buried insulating layer 201, and then by burying an insulating material inside the element isolation trench. The cell region element isolation film STI is formed, and the cell array region CAR may be defined. The upper surface of the cell region element isolation film STI may be substantially coplanar with the upper surface of the mask pattern MP.

A plurality of active pattern isolation structures APBK may be formed inside the active layer 202. The active pattern isolation structures APBK are disposed inside the cell array region CAR. The active pattern isolation structures APBK may be arranged in the second direction D2. The active pattern isolation structures APBK may include, for example, silicon oxide.

The active pattern isolation structure APBK may be spaced apart from the cell region element isolation film STI. Unlike the shown example, the active pattern isolation structure APBK may be formed to be in contact with the cell region element isolation film STI.

From viewpoint of a plan view, although the active pattern isolation structure APBK is shown as being a square, the example embodiments are not limited thereto. Unlike the shown example, the active pattern isolation structure APBK may have a shape such as a square with rounded corners, an ellipse, and a circle.

Unlike the aforementioned example, the active pattern isolation structure APBK may be formed inside the active layer 202 before the mask pattern MP is formed. In such a case, the mask pattern MP may be formed on the active pattern isolation structure APBK.

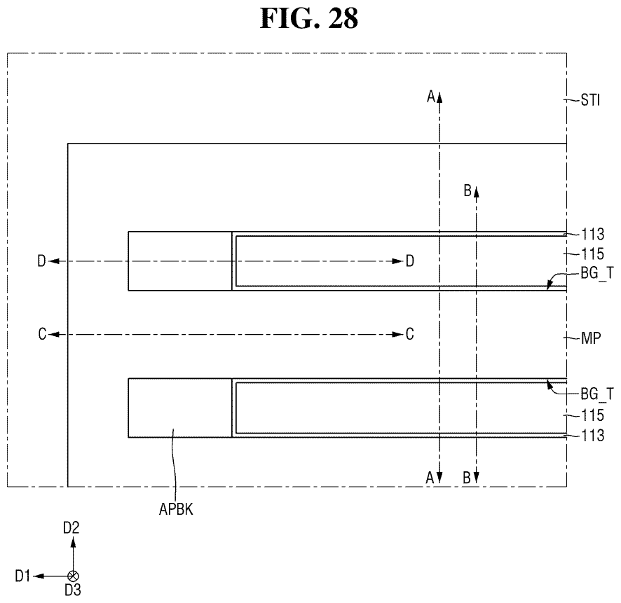

Referring to FIGS. 28 to 30, the active layer 202 of the cell array region CAR may be anisotropically etched.

Therefore, back gate trenches BG_T extending in the first direction D1 may be formed in the active layer 202 of the cell array region CAR. The back gate trenches BG_T may expose the buried insulating layer 201, and may be spaced apart at regular intervals in the second direction D2. Each back gate trench BG_T may join each active pattern isolation structure APBK. The back gate trench BG_T may extend from the active pattern isolation structure APBK in the first direction D1.

Unlike the shown example, at least a part of the buried insulating layer 201 may be removed, while the back gate trench BG_T is being formed.

Thereafter, the back gate insulating patterns 113 and the back gate electrodes BG may be formed inside the back gate trench BG_T. The back gate insulating pattern 113 may be in contact with the active pattern isolation structure APBK.

More specifically, the back gate insulating pattern 113 may be formed along the side wall and bottom surface of the back gate trench BG_T and the upper surface of the mask pattern MP. The back gate conductive film may be formed on the back gate insulating pattern 113. The back gate conductive film may fill the back gate trench BG_T. Subsequently, the back gate conductive film may be etched to form back gate electrodes BG extending in the first direction D1. The back gate electrodes BG may partially fill the back gate trench BG_T.

Meanwhile, according to some example embodiments, a gas phase doping (GPD) process or a plasma doping (PLAD) process may be performed before forming the back gate insulating pattern 113. Through the aforementioned process, the active layer 202 exposed by the back gate trench BG_T may be doped with impurities.

Thereafter, the back gate capping patterns 115 may be formed on the back gate electrode BG.

The back gate capping pattern 115 may fill the remainder of the back gate trench BG_T. When the back gate capping pattern 115 and the back gate insulating pattern 113 are formed of the same material (for example, silicon oxide), the back gate insulating pattern 113 on the upper surface of the mask pattern MP may be removed during the formation of the back gate capping pattern 115.

Meanwhile, before forming the back gate capping pattern 115, the gas phase doping (GPD) process or the plasma doping (PLAD) process may be performed. Therefore, the active layer 202 may be doped with impurities through the back gate trench BG_T in which the back gate electrode BG is formed.

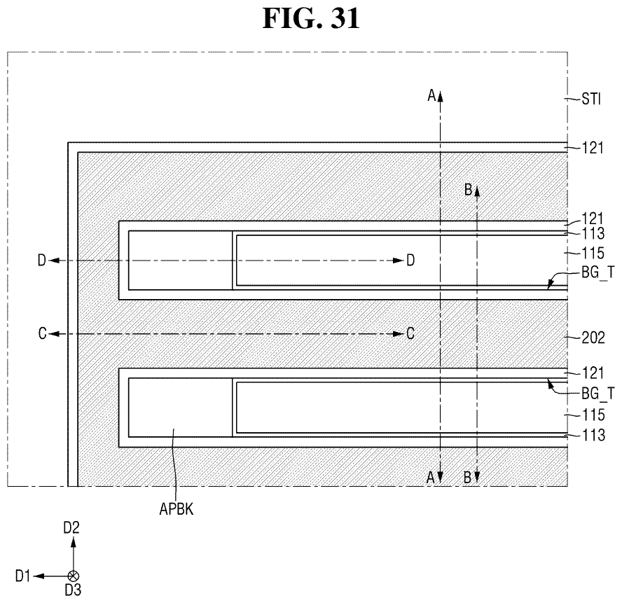

Referring to FIGS. 31 to 33, after forming the back gate capping patterns 115, the upper mask film 12 may be removed.

The back gate capping patterns 115 may have a shape which protrudes upward beyond the upper surface of the lower mask film 11. The active pattern isolation structures APBK may have a shape that protrudes upward beyond the upper surface of the lower mask film 11.

Subsequently, a pair of spacer patterns 121 may be formed on the side walls of the back gate insulating pattern 113. The spacer pattern 121 may also be formed on the side walls of the active pattern isolation structure APBK.

While the upper mask film 12 is being removed, a part of the cell region element isolation film STI may be removed. Accordingly, a step structure may be formed along the boundary of the active layer 202 of the cell array region CAR. The spacer pattern 121 may be formed on the step structure of the cell region element isolation film STI.

More specifically, the spacer film may be formed along the upper surface of the lower mask film 11, the side walls of the back gate insulating patterns 113, and the upper surfaces of the back gate capping patterns 115. A spacer film may be formed along the side walls of the active pattern isolation structure APBK and the upper surface of the active pattern isolation structure APBK. The spacer film may be formed to have a uniform thickness. The spacer pattern 121 may be formed by performing an anisotropic etching process on the spacer film. The active layer 202 may be exposed while the spacer pattern 121 is being formed.

The widths of the active patterns of the vertical channel transistors may be determined depending on the deposited thickness of the spacer film. The spacer film may be formed of an insulating material. The spacer film may include, for example, silicon oxide, silicon oxynitride, silicon nitride, silicon carbide (SiC), silicon carbon nitride film (SiCN), combinations thereof, and the like.

Referring to FIGS. 31 to 36, the anisotropic etching process may be performed on the active layer 202, using the spacer pattern 121 as an etching mask.

Accordingly, pre-active patterns PAP extending along each back gate electrode BG may be formed. As the pre-active patterns PAP are formed, the buried insulating layer 201 may be exposed. The pre-active pattern PAP may be formed along the side walls of the active pattern isolation structure APBK.

While the pre-active pattern PAP is being formed, a word line trench WL_T is formed.

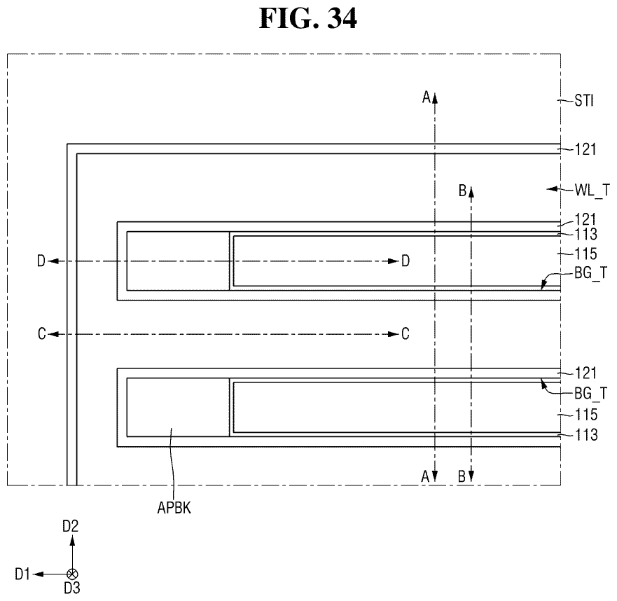

Referring to FIGS. 34 to 39, a sacrificial film which fills the word line trench WL_T may be formed.

The active mask pattern may be formed on the sacrificial film. The active mask pattern may have a linear form extending in the second direction D2. As another example, the active mask pattern may have the linear form extending in the diagonal direction with respect to the first direction D1 and the second direction D2. The sacrificial film may be etched using the active mask pattern as an etch mask to form sacrificial openings inside the sacrificial film.

By etching the pre-active patterns PAP exposed to the sacrificial openings, the first active pattern AP1 and the second active pattern AP2 may be formed on both sides of the back gate electrode BG. The first active patterns AP1 may be formed on the first side wall of the back gate electrode BG to be spaced apart from each other in the first direction D1. The second active patterns AP2 may be formed on the second side wall of the back gate electrode BG to be spaced apart from each other in the first direction D1. Since the first active pattern AP1 and the second active pattern AP2 are formed, the sacrificial openings may expose a part of the back gate insulating pattern 113.

In addition, the first dummy active pattern APD1 and the second dummy active pattern APD2 may be formed on both sides of the back gate electrode BG. The first dummy active pattern APD1 may be spaced apart from the first active pattern AP1 in the first direction D1. The second dummy active pattern APD2 may be spaced apart from the second active pattern AP2 in the first direction D1.

Then, the sacrificial film, the active mask pattern, the spacer pattern 121, and the lower mask film 11 may be removed. Accordingly, the first active pattern AP1, the second active pattern AP2, the first dummy active pattern APD1, and the second dummy active pattern APD2 may be exposed. Further, the buried insulating layer 201 may be exposed.

Unlike the shown example, the first dummy active pattern APD1 and the second dummy active pattern APD2 may not be formed on both sides of the back gate electrode BG.

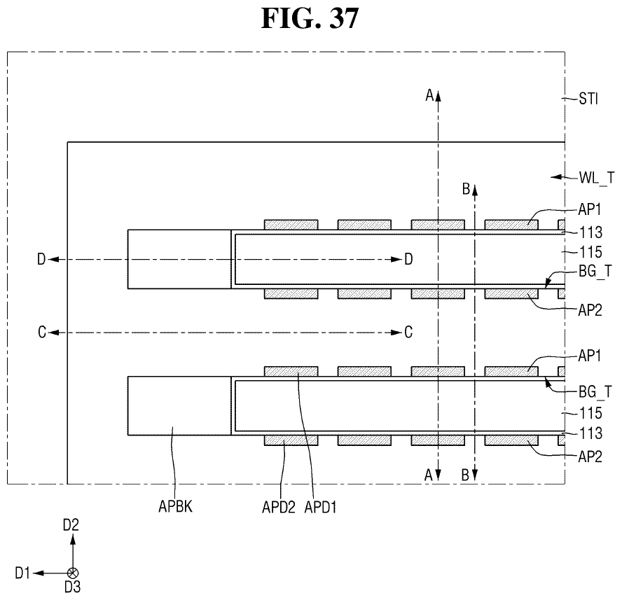

Referring to FIGS. 37 to 40, the gate insulating pattern GOX may be formed along the side walls of the first active pattern AP1, the side walls of the second active pattern AP2, the side walls of the first dummy active pattern APD1, the side walls of the second dummy active pattern APD2, the upper surface of the gate capping pattern 115, and the upper surface of the buried insulating layer 201.

The gate insulating pattern GOX may be formed along the side walls of the cell region element isolation film STI and the side walls of the active pattern isolation structure APBK.

The gate insulating pattern GOX may be formed by using, but not limited to, at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) techniques.

Subsequently, a pre-word line WL_P1 may be formed on the gate insulating pattern GOX. The pre-word line WL_P1 may be formed on the side walls of the first and second active patterns AP1 and AP2. The pre-word line WL_P1 may be formed on the side walls of the cell region element isolation film STI and the side walls of the active pattern isolation structure APBK. The pre-word line WL_P1 extending along the side wall of the cell region element isolation film STI may include a first portion extending in the first direction D1 and a second portion extending in the second direction D2.

Formation of the pre-word line WL_P1 may include depositing of the gate conductive film on the gate insulating pattern GOX, and then performing of the anisotropic etching process on the gate conductive film. Here, a deposited thickness of the gate conductive film may be smaller than half the width of the word line trench WL_T.

At the time of the anisotropic etching process on the gate conductive film, the gate insulating pattern GOX may be used as an etching stop film. Unlike the shown example, the gate insulating pattern GOX may be over-etched, and the buried insulating layer 201 may be exposed.

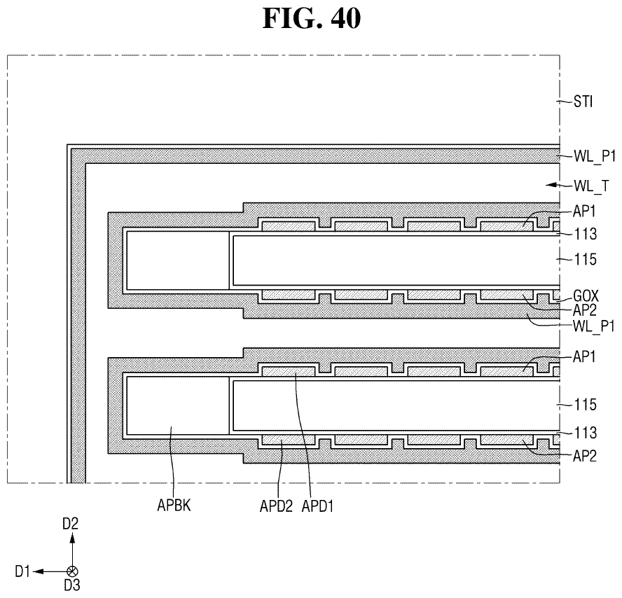

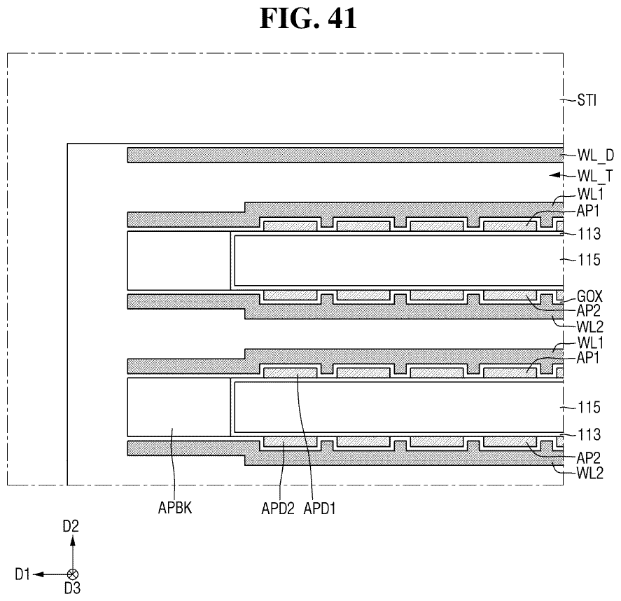

Referring to FIGS. 40 and 41, a part of the pre-word line WL_P1 may be removed to form a first word line WL1, a second word line WL2, and a dummy word line WL_D.

In the pre-word line WL_P1 extending along the side wall of the cell region element isolation film STI, a portion extending in the second direction D2 may be removed. Furthermore, the pre-word line WL_P1 extending in the second direction D2 along the side wall of the active pattern isolation structure APBK may be removed.

Unlike the shown example, while the second word line WL2 and the dummy word line WL_D are being formed, a portion extending in the first direction D1 in the pre-word line WL_P1 extending along the side wall of the cell region element isolation film STI may also be removed.

The upper surface of the dummy word line WL_D, the upper surface of the first word line WL1, and the upper surface of the second word line WL2 may be located at a lower level than the upper surfaces of the first and second active patterns AP1 and AP2.

As an example, after forming the dummy word line WL_D and the word lines WL1 and WL2, a gas phase doping GPD process or a plasma doping PLAD process may be performed. Accordingly, impurities may be doped into the first and second active patterns AP1 and AP2 through the gate insulating pattern GOX exposed by the first and second word lines WL1 and WL2. While the first and second active patterns AP1 and AP2 are being doped with impurities, the first and second dummy active patterns APD1 and APD2 may be doped with impurities.

Referring to FIGS. 41 to 44, the gate isolation pattern GSS may be formed on the first word line WL1, the second word line WL2, and the dummy word line WL_D.

For example, the upper surface of the gate separation pattern GSS may be disposed on the same plane as the upper surface of the back gate capping pattern 115.

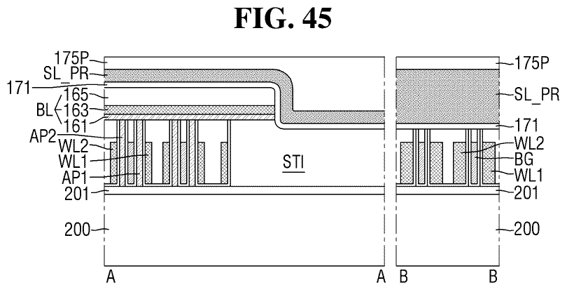

Referring to FIGS. 45 to 48, the bit line BL and the dummy bit line BL_D may be formed on the first and second active patterns AP1 and AP2 and the first and second dummy active patterns (APD1 and APD2 of FIG. 2).

The bit line BL may be formed on the first active pattern AP1 and the second active pattern AP2. The bit line BL may be connected to the first active pattern AP1 and the second active pattern AP2.

The dummy bit line BL_D may be formed on the first dummy active pattern APD1 and the second dummy active pattern APD2.

The shielding insulation liner 171 may then be formed along the profile of the bit line BL and the profile of the dummy bit line BL_D.

The pre-shielding conductive pattern SL_PR and the pre-shielding insulation capping film 175P may be formed on the shielding insulation liner 171. The pre-shielding conductive pattern SL_PR may fill the space between the bit lines BL adjacent to each other in the first direction D1 and the space between the bit line BL and the dummy bit line BL_D adjacent to each other in the first direction D1.

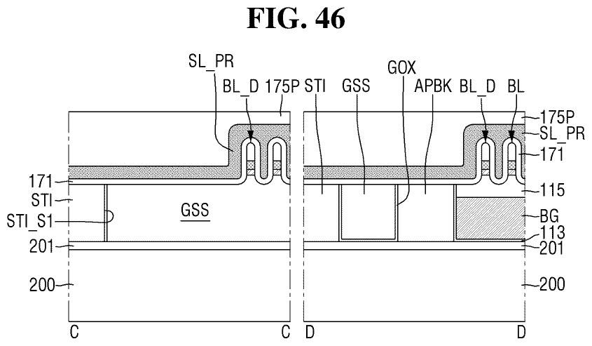

In FIGS. 45 and 46, the pre-shielding conductive pattern SL_PR may be formed along the profile of the shielding insulation liner 171. The pre-shielding conductive pattern SL_PR may be uniformly formed on the bit line BL and the cell region element isolation film STI. The height of the upper surface of the pre-shielding conductive pattern SL_PR on the bit line BL may be higher than the height of the upper surface of the pre-shielding conductive pattern SL_PR on the cell region element isolation film STI.

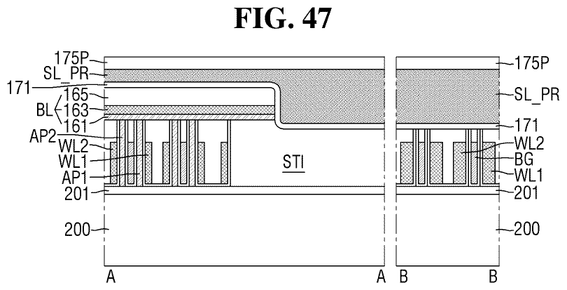

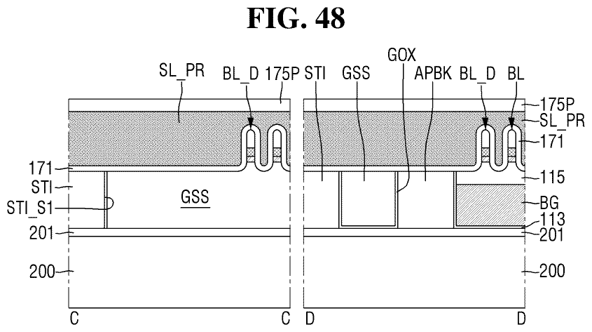

In FIGS. 47 and 48, the thickness of the pre-shielding conductive pattern SL_PR on the bit line BL is smaller than the thickness of the pre-shielding conductive pattern SL_PR on the cell region element isolation film STI. From viewpoint of a cross-sectional view, the upper surface of the pre-shielding conductive pattern SL_PR may be similar to, for example, a plane.

Referring to FIGS. 45 to 52, the shielding conductive pattern SL may be formed by patterning the pre-shielding conductive pattern SL_PR.

In FIGS. 45, 46, 49, and 50, the shielding conductive pattern SL may include a shielding conductive plate SLh and a plurality of shielding conductive line patterns SLp. More specifically, the mask pattern may be formed at the position where the shielding conductive plate SLh is formed. The pre-shielding conductive pattern SL_PR and the pre-shielding insulation capping film 175P may be removed, using the mask pattern. Accordingly, the shielding conductive pattern SL and the shielding insulation capping film 175 may be formed. Subsequently, the first upper interlayer insulating film 263 may be formed. For example, the shielding insulation capping film 175 may include a first portion 175_1 and a second portion 175_2. The first portion 175_1 of the shielding insulation capping film may be a portion that remains after the pre-shielding insulation capping film 175P is etched. The second portion 175_2 of the shielding insulation capping film may be formed during the formation of the first upper interlayer insulating film 263.

In FIGS. 47, 48, 51, and 52, the pre-shielding conductive pattern SL_PR formed on the bit line BL is removed, and the shielding conductive pattern SL including a plurality of shielding conductive line patterns SLp may be formed. The shielding conductive pattern SL does not include the shielding conductive plate SLh. While the shielding conductive pattern SL is being formed, the pre-shielding insulation capping film 175P may also be etched. In such a case, unlike the shown example in FIGS. 47 and 48, the pre-shielding insulation capping film 175P may not be formed on the pre-shielding conductive pattern SL_PR.

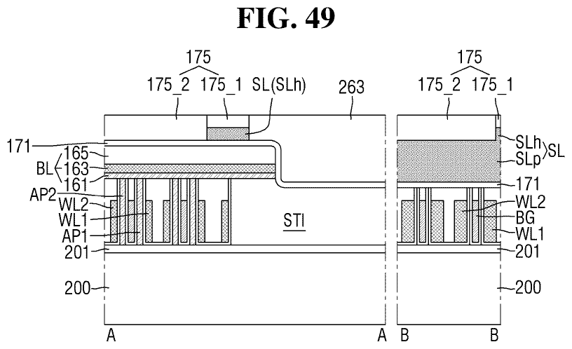

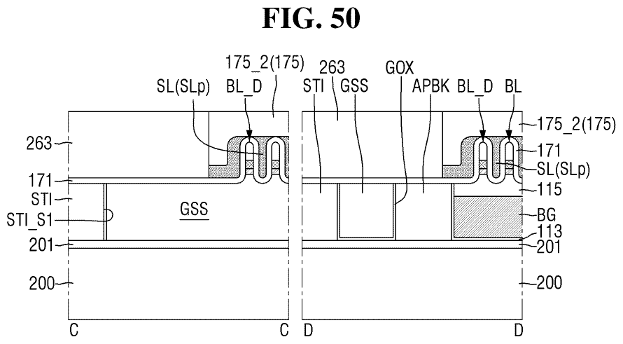

Although FIGS. 49 and 50 are shown to proceed after FIGS. 45 and 46 proceed, the example embodiments are not limited thereto. It goes without saying that the processes shown in FIGS. 49 and 50 may also proceed in the states shown in FIGS. 47 and 48.

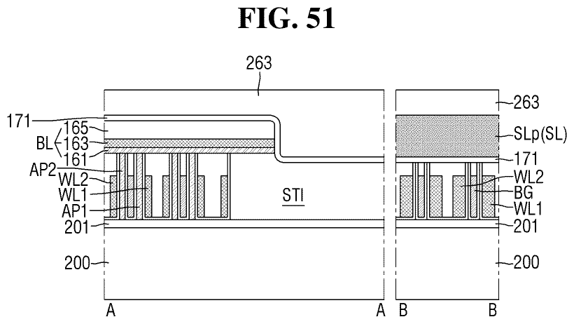

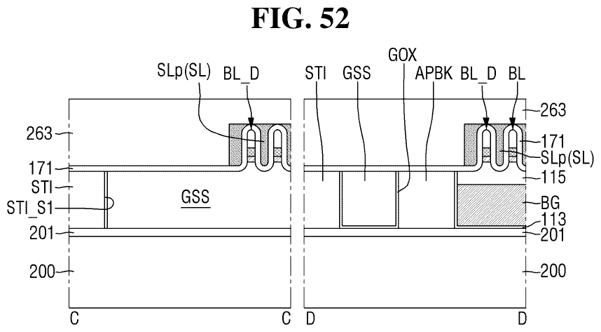

Although FIGS. 51 and 52 are shown to proceed after FIGS. 47 and 48 proceed, the example embodiments are not limited thereto. It goes without saying that the processes shown in FIGS. 51 and 52 may also proceed in the states shown in FIGS. 45 and 46.

The subsequent processes will be explained using FIGS. 49 and 50.

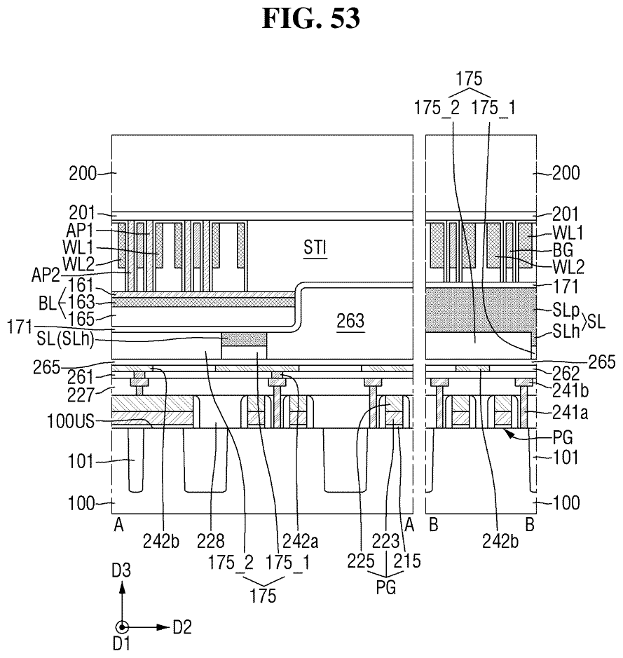

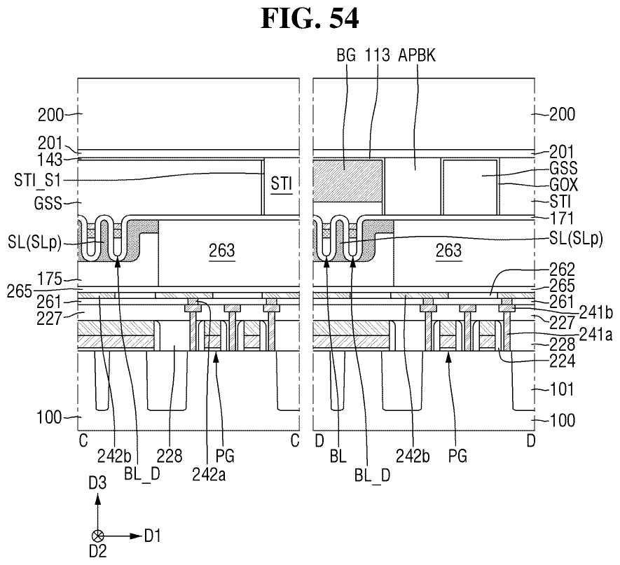

Referring to FIGS. 53 and 54, a sub-substrate 200 on which the back gate electrodes BG, the word lines WL1 and WL2, the active patterns AP1 and AP2, the bit lines BL, and the shielding conductive patterns SL are formed may be bonded to the substrate 100.

In other words, the substrate 100 on which the peri-gate structure PG and the peri-connecting structures 242a and 242b are formed may be bonded to the sub-substrate 200.

Referring to FIGS. 53 to 56, after bonding the sub-substrate 200 and the substrate 100, a back lapping process for removing the sub-substrate 200 may be performed.

Removal of the sub-substrate 200 may include exposing the buried insulating layer 201 by sequentially performing a grinding process and a wet etching process.

Next, the buried insulating layer 201 may be removed to expose the first active pattern AP1 and the second active pattern AP2. The buried insulating layer 201 may be removed to expose a part of the gate insulating pattern GOX and a part of the back gate insulating pattern 113.

Thereafter, the exposed gate insulating pattern GOX and the exposed back gate insulating pattern 113 may be removed. Therefore, the back gate electrode BG, the first word line WL1, and the second word line WL2 may be exposed.

Thereafter, an etch-back process may be performed to remove a part of the first word line WL1 and a part of the second word line WL2. A gate capping pattern 143 may be formed on the recessed first and second word lines WL1 and WL2.

By performing an etch-back process, a part of the back gate electrode BG may be removed. A back gate isolation pattern 111 may be formed on the recessed back gate electrode BG.

A contact hole that exposes the first active pattern AP1 and the second active pattern AP2 may be formed inside the contact interlayer insulating film 231.

The contact pattern BC may be formed inside the contact hole. The contact patterns BC may be formed on the first active pattern AP1 and the second active pattern AP2. The contact patterns BC may be connected to the first active pattern AP1 and the second active pattern AP2.

Further, a bit line contact plug 281a connected to the bit line BL may be formed. An upper peripheral contact plug 283a may be formed. An upper peripheral contact plug 283a connected to the peri-connecting wiring 242b may be formed.

Next, the landing pad LP may be formed on the contact pattern BC. The landing pad LP may be formed inside the pad isolation insulating film 245. The upper connecting wiring 282a may be formed inside the pad isolation insulating film 245. The upper connecting wiring 282a may connect the bit line contact plug 281a and the upper peripheral contact plug 283a.

Next, referring to FIGS. 3 and 4, the data storage patterns DSP may be formed on landing pad LP.

In concluding the detailed description, those skilled in the art will appreciate that many variations and modifications may be made to the example embodiments without substantially departing from the principles of the present inventive concepts. Therefore, the disclosed example embodiments of the disclosure are used in a generic and descriptive sense only and not for purposes of limitation.

What is claimed is:

1. A semiconductor memory device comprising:
a peri-gate structure on a substrate;
a shielding conductive pattern on the peri-gate structure, the shielding conductive pattern including shielding line patterns extending in a first direction;
a bit line between the shielding line patterns adjacent in a second direction on the peri-gate structure, the bit lines extend in the first direction;
first and second active patterns which alternate on the bit line in the first direction;
a back gate electrode on the bit line and the shielding conductive pattern, the back gate electrode between the first and second active patterns adjacent to each other, the back gate electrode extending in the second direction;
a first word line adjacent to the first active patterns, and extend in the second direction;
second word lines adjacent to the second active patterns, the second word lines extending in the second direction; and
a data storage pattern on the first active pattern and the second active pattern, the data storage pattern connected to the first active pattern and the second active pattern,
wherein the bit line includes a first portion of the bit line and a second portion on at least one side of the first portion of the bit line,
the first portion of the bit line overlaps the shielding line patterns in the second direction, and
the second portion of the bit line does not overlap the shielding line patterns in the second direction.

2. The semiconductor memory device of claim 1,
wherein the shielding conductive pattern further includes a first shielding plate connected to the shielding line patterns, and
a length of the first shielding plate in the first direction is smaller than a length of the shielding line patterns in the first direction.

3. The semiconductor memory device of claim 2,
wherein the bit line is on the first shielding plate.

4. The semiconductor memory device of claim 2,
wherein the shielding conductive pattern further includes a second shielding plate that is connected to the shielding line patterns and is spaced apart from the first shielding plate in the first direction, and
the length of the second shielding plate in the first direction is smaller than the length of the shielding line patterns in the first direction.

5. The semiconductor memory device of claim 2,
wherein the first shielding plate does not overlap the first active pattern and the second active pattern in a vertical direction.

6. The semiconductor memory device of claim 1,
wherein the bit line includes a bottom surface which faces the peri-gate structure, and an upper surface which faces the first and second active patterns, and
the shielding conductive pattern is not on the bottom surface of the bit line.

7. The semiconductor memory device of claim 6,
wherein the shielding line patterns include bottom surfaces which face the peri-gate structure, and
the bottom surface of the bit line is higher than the bottom surfaces of the shielding line patterns with respect to an upper surface of the substrate.

8. The semiconductor memory device of claim 6, further comprising:
a shielding strap structure on the shielding conductive pattern,
wherein the shielding strap structure includes a strap via connected to the shielding line patterns, and a shielding strap line connected to the shielding strap via and extending in the second direction.

9. The semiconductor memory device of claim 1,
wherein the second portion of the bit line is on both sides of the first portion of the bit line.

10. The semiconductor memory device of claim 1,
wherein the first active pattern includes a first side wall and a second side wall opposite to each other in the first direction, and a first surface and a second surface opposite to each other in a vertical direction,
the back gate electrode is on the first side wall of the first active pattern,
the first word line is on the second side wall of the first active pattern,
the bit line is connected to the first surface of the first active pattern, and
the data storage pattern is connected to the second surface of the first active pattern.

11. The semiconductor memory device of claim 1,
wherein the first word line includes a first portion and a second portion that alternate in the second direction, and
a width of the first portion of the first word line in the first direction is smaller than a width of the second portion of the first word line in the first direction.

12. A semiconductor memory device comprising:
a peri-gate structure on a substrate;
a shielding conductive pattern on the peri-gate structure, the shielding conductive pattern including a first shielding plate and a plurality of shielding line patterns, each shielding line pattern of the plurality of shielding line patterns extending in a first direction;
a bit line on the peri-gate structure between shielding line patterns of the plurality of shielding line patterns adjacent in a second direction, the bit line extend in the first direction;
first and second active patterns which alternate on the bit line in the first direction;
a back gate electrode on the bit line and the shielding conductive pattern, the back gate electrode between the first and second active patterns adjacent to each other, the back gate electrode extending in the second direction;
first word lines adjacent to the first active patterns, the first word lines extending in the second direction;
second word lines adjacent to the second active patterns, the second word lines extending in the second direction; and
a data storage pattern on the first active pattern and the second active pattern, the data storage pattern connected to the first active pattern and the second active pattern,
wherein each of the plurality of shielding line patterns includes a first portion that overlaps the first shielding plate in a vertical direction and a second portion that does not overlap the first shielding plate in the vertical direction.

13. The semiconductor memory device of claim 12,
wherein a part of the bit line protrudes in the first direction beyond the plurality of shielding line patterns.

14. The semiconductor memory device of claim 12, further comprising:
a shielding insulation capping film between the peri-gate structure and the shielding conductive pattern, the shielding insulation capping film is in contact with the shielding conductive pattern,
wherein a thickness of the shielding insulation capping film between the first portion of the plurality of shielding line patterns and the peri-gate structure is smaller than a thickness of the shielding insulation capping film between the second portion of the plurality of shielding line patterns and the peri-gate structure.

15. The semiconductor memory device of claim 12,
wherein the first shielding plate does not overlap the first active pattern and the second active pattern in the vertical direction.

16. The semiconductor memory device of claim 12,
wherein each of the shielding conductive pattern further include a second shielding plate spaced apart from the first shielding plate in the first direction, and
each of the shielding line patterns includes a third portion that overlaps the second shielding plate in the vertical direction.

17. The semiconductor memory device of claim 16,
wherein the second portion of each of the shielding line patterns are between the first portion of the shielding line patterns and the third portion of the shielding line patterns.

18. A semiconductor memory device comprising:
a peri-gate structure on a substrate;
a bit line on the peri-gate structure, the bit line extending in a first direction;
a shielding conductive pattern on the peri-gate structure between bit lines adjacent in a second direction, the shielding conductive pattern including a plurality of shielding line patterns extending in the first direction;
first and second active patterns which alternate on the bit line in the first direction;
a back gate electrode on the bit line and the shielding conductive pattern, the back gate electrode extending in the second direction between adjacent first and second active patterns;
first word lines adjacent to the first active patterns and extending in the second direction;
second word lines adjacent to the second active patterns and extending in the second direction; and
a data storage pattern on the first active pattern and the second active pattern, the data storage pattern is connected to the first active pattern and the second active pattern,
wherein a part of the bit line protrudes beyond the plurality of shielding line patterns in the first direction,
the bit line includes a bottom surface facing the peri-gate structure, and an upper surface facing the first and second active patterns, and
the shielding conductive pattern is not on the bottom surface of the bit line.

19. The semiconductor memory device of claim 18,
wherein each shielding line pattern of the plurality of shielding line patterns includes a bottom surface facing the peri-gate structure, and
the bottom surface of the bit line is higher than the bottom surface of the shielding line patterns on a basis of the upper surface of the substrate.

20. The semiconductor memory device of claim 18, further comprising:
a shielding strap structure on the shielding conductive pattern,
wherein the shielding strap structure includes a strap via connected to the plurality of shielding line patterns, and a shielding strap line connected to the shielding strap via and extending in the second direction.
